(19) United States
(12) Patent Application Publication
(10) Pub. No.: US 2024/0295617 A1
(43) Pub. Date: Sep. 5, 2024

(54) Connecting Quantum Processor Chips in a Modular Quantum Processing Unit

(71) Applicant: Rigetti & Co, LLC, Berkeley, CA (US)

(72) Inventors: Andrew Joseph Bestwick, Berkeley, CA (US); Benjamin Charles Scharmann, New York, NY (US); Mark Field, Campbell, CA (US)

(73) Assignee: Rigetti & Co, LLC, Berkeley, CA (US)

(21) Appl. No.: 18/605,489

(22) Filed: Mar. 14, 2024

Related U.S. Application Data
(63) Continuation of application No. PCT/US22/43862, filed on Sep. 16, 2022.
(60) Provisional application No. 63/245,019, filed on Sep. 16, 2021.
(60) Provisional application No. 63/313,164, filed on Feb. 23, 2022.
(60) Provisional application No. 63/343,453, filed on May 18, 2022.

(51) Int. Cl. G01R 33/035; G06N 10/40

(52) U.S. Cl. CPC G01R 33/0358; G06N 10/40

(57) ABSTRACT

In a general aspect, a modular quantum processing unit (QPU) includes quantum processor chips inter-connected by a cap structure. In some cases, a modular quantum processing unit includes a tunable-frequency coupler device, a first quantum processor chip, a second quantum processor chip, and a cap structure. The tunable-frequency coupler device includes a superconducting quantum interference device (SQUID) loop, a shunt capacitor, and a flux bias control line that controls a magnetic flux through the SQUID loop. The first quantum processor chip includes a first qubit device, the SQUID loop, the flux bias control line, and a first capacitive coupler device galvanically connected between the first qubit device and the tunable-frequency coupler device. The second quantum processor chip includes a second qubit device. The cap structure, which includes a microwave transmission line capacitively coupled between the tunable-frequency coupler device and the second qubit device, is bonded to the first and second quantum processor chips.

### CROSS-REFERENCE TO RELATED APPLICATIONS

This application claims priority to U.S. Provisional Patent Application No. 63/245,019, filed Sep. 16, 2021, entitled “Connecting Quantum Processor Modules in a Modular Quantum Processing Unit;” U.S. Provisional Patent Application No. 63/313,164, filed Feb. 23, 2022, entitled “Multi-chip Quantum Processor Configurations;” and U.S. Provisional Patent Application No. 63/343,453, filed May 18, 2022, entitled “Module Integration Plate with Inter-module Connections for Modular Quantum Processor Configurations.” The above-referenced priority documents are incorporated herein by reference in their entireties.

### BACKGROUND

Quantum computers can perform computational tasks by storing and processing information within quantum states of quantum systems. For example, qubits (i.e., quantum bits) can be stored in and represented by an effective two-level sub-manifold of a quantum coherent physical system. A variety of physical systems have been proposed for quantum computing applications. Examples include superconducting circuits, trapped ions, spin systems, and others.

### BRIEF DESCRIPTION OF THE DRAWINGS

FIG. 1 is a block diagram of an example computing environment.

FIG. 2 is a schematic diagram showing aspects of a top view of an example modular quantum processing unit.

FIGS. 3A-3D are equivalent circuit diagrams of example modular quantum processing units.

FIG. 4 is a schematic diagram showing aspects of an example tunable-frequency coupler device.

FIGS. 5A-5B are schematic layout diagrams of top views of example modular quantum processing units.

FIG. 6 is an equivalent circuit diagram of an example modular quantum processing unit.

FIG. 7 is an equivalent circuit diagram of an example modular quantum processing unit.

FIG. 8 is a schematic diagram of a perspective view of an example modular quantum processing unit.

FIG. 9 is a schematic diagram showing aspects of an example modular quantum processing unit.

FIG. 10 is a schematic diagram showing top-view and cross-sectional view of an example module integration plate.

### DETAILED DESCRIPTION

In some aspects of what is described here, a modular quantum processing unit includes multiple quantum processor chips. Each of the quantum processor chips includes superconducting quantum circuit devices and superconducting circuitry forming a superconducting quantum integrated circuit (QuIC). Two qubit devices (e.g., two qubit devices in distinct quantum processor chips) can be coupled to each other by a tunable-frequency coupler device that is capacitively coupled to each of the two qubit devices. In some implementations, a tunable-frequency coupler device has a lossless resonator structure. For example, a tunable-frequency coupler device may include a superconducting circuit loop with at least two Josephson junctions connected in parallel, a shunt capacitor, and superconductive lines that connect these circuit elements. A tunable-frequency coupler device coupled between qubit devices can reduce coherent errors and can be tuned to reduce unwanted direct interaction between the qubit devices, for example, when quantum logic gate operations are not performed.

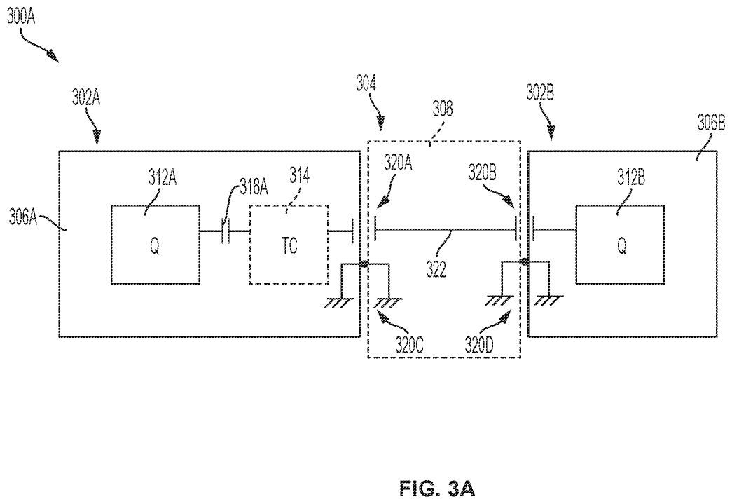

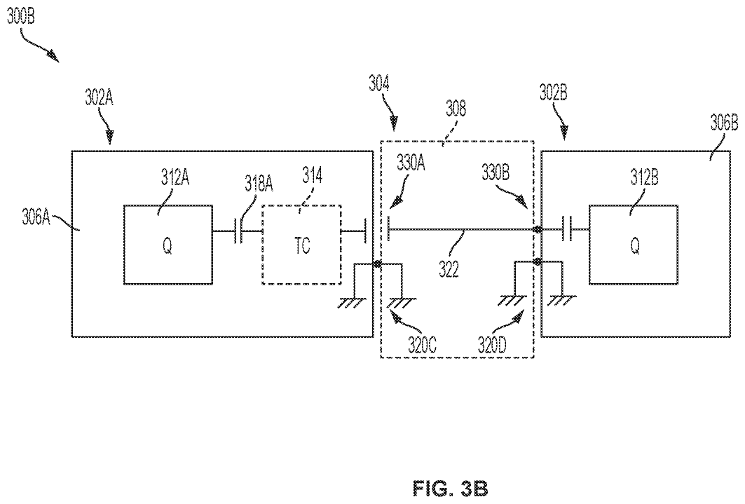

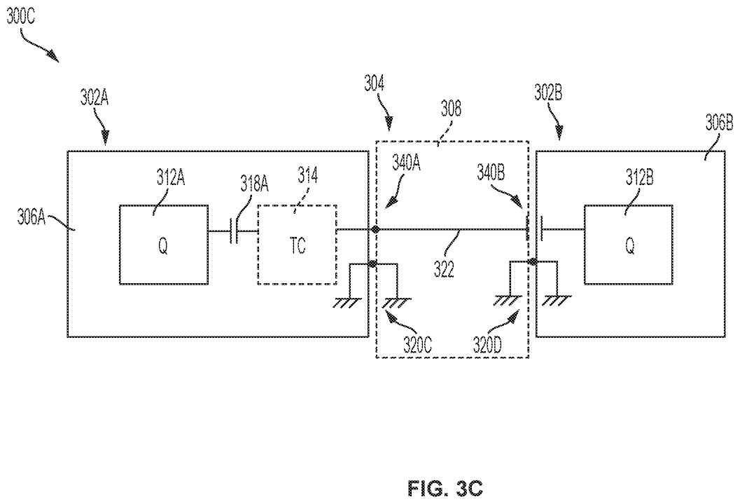

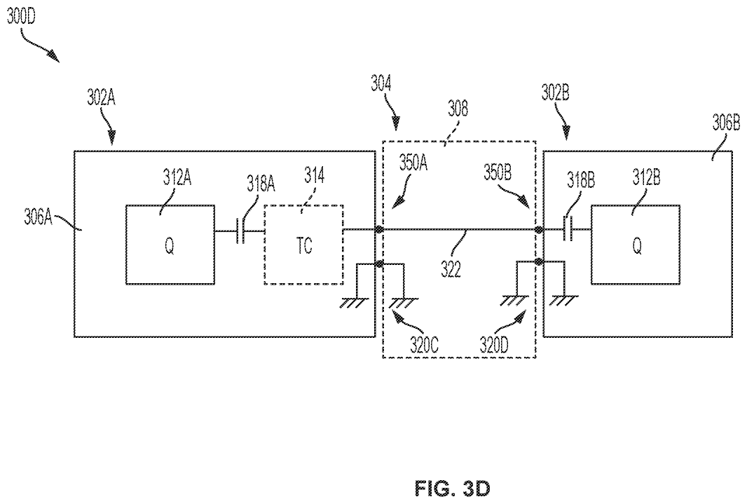

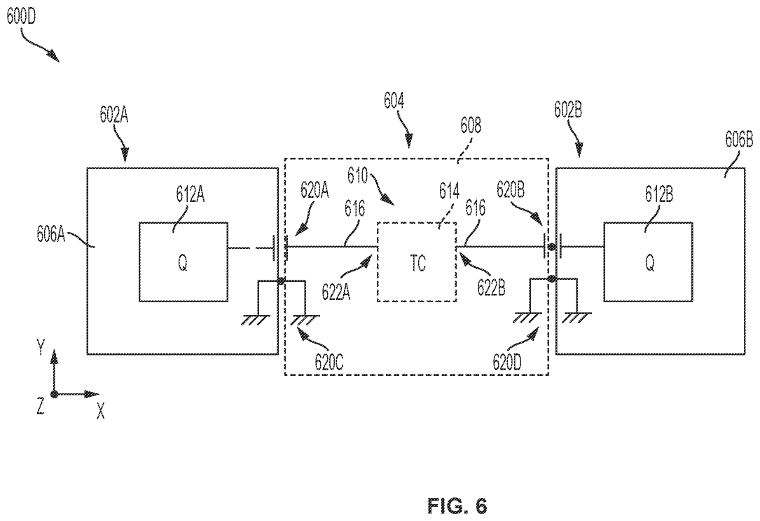

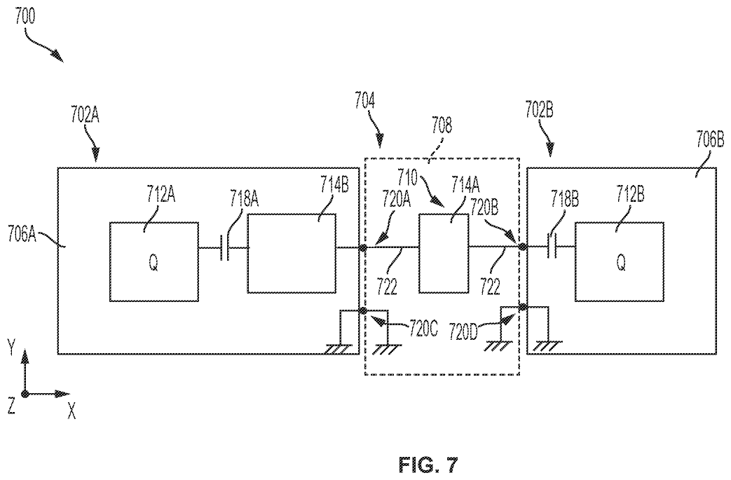

In some implementations, a cap structure of the modular quantum processing unit includes inter-chip coupler devices, which are configured to bond different quantum processor chips together and to provide inter-chip coupling between quantum circuit devices from different quantum processor chips. In some implementations, an inter-chip coupler device includes a microwave transmission line that is coupled to a quantum circuit device (e.g., a tunable-frequency coupler device that is further capacitively coupled to a first qubit device) on a first quantum processor chip and coupled to a quantum circuit device (e.g., a second qubit device) on a second quantum processor chip (e.g., as in the example modular quantum processing units 300A, 300B, 300C, 300D in FIGS. 3A-3D). In certain implementations, an inter-chip coupler device on the cap structure includes a tunable-frequency coupler device and microwave transmission lines (e.g., as in the example modular quantum processing unit 600 in FIG. 6). In some implementations, an inter-chip coupler device on the cap structure includes a portion of a tunable-frequency coupler device, while the rest of the tunable-frequency coupler device may reside on the surface of one or more quantum processor chips (e.g., as in the example modular quantum processing unit 700 in FIG. 7).

In some implementations, using inter-chip coupler devices in the cap structure to interconnect quantum processor chips can provide technical advantages and improvements over other techniques. For example, the methods and techniques presented here may allow dense packing of quantum circuit devices on chips and hence compact structures in quantum computing architectures. These compact structures are likely to have a higher quality factor (Q) at cryogenic temperatures as the quantum circuit devices interact with fewer localized quantum two-level systems that appear randomly in some materials and act as energy loss channels that cause decoherence. These compact structures can also include 3D designs where capacitance or inductance elements can be implemented as vertical metal structures created in the substrate of a quantum processor chip or a cap structure.

In some implementations, the methods and techniques presented here may improve microwave performance. For example, the fidelity of 2-qubit quantum logic gates applied on qubits defined by qubit devices located on separate quantum processor chips can be improved. The methods and techniques presented here may also allow a standard design of cap structures to be integrated with different designs of quantum processor chips, which simplifies the fabrication process and reduces downtime, for example, when upgrading. The methods and techniques presented here may also allow chips with different functions such as input/output devices, quantum memory, or elements that transduce the coherent microwave signal to a different modality, such as optical quantum processing units. Further, the methods and techniques presented here may allow the ability to rapidly iterate designs. For instance, the methods and techniques presented here may allow a design for manufacturability in which structures that are dissimilar in size, aspect ratio, materials being processed, substrate morphology, or process tools used during manufacture can be separated and the yield of devices can be improved.

In some implementations, the methods and techniques presented here may reduce cross-talk and correlated errors between quantum processor chips. For example, when error correction is used in a modular quantum processing unit (e.g., using error correction schemes such as surface-code error correction), quantum information can be distributed over many qubit devices which allows errors to be detected and corrected. Correlated errors caused by absorbed heat can cause qubits to lose coherence. The methods and techniques presented here may allow better heatsinking from superconducting QuICs on the quantum processor chips to the refrigeration system by providing additional thermal dissipation paths to the quantum processor chips through the cap structure. The methods and techniques presented here may also allow error correction code to be distributed among qubit devices on different quantum processor chips and thus allow the system to recover when external radiation is absorbed in one of the superconducting QuICs. In some implementations, the methods and techniques described here using multichip modular designs can also be used to improve performance of other superconducting radio frequency electronics modules. In some cases, a combination of these and potentially other advantages and improvements may be obtained.

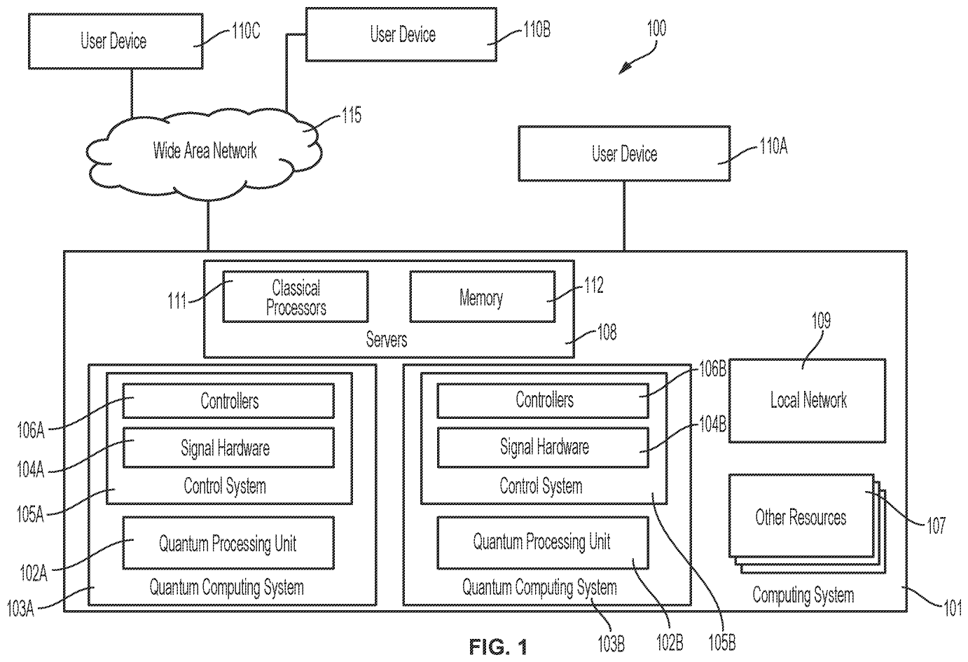

FIG. 1 is a block diagram of an example computing environment 100. The example computing environment 100 shown in FIG. 1 includes a computing system 101 and user devices 110A, 110B, 110C. A computing environment may include additional or different features, and the components of a computing environment may operate as described with respect to FIG. 1 or in another manner.

The example computing system 101 includes classical and quantum computing resources and exposes their functionality to the user devices 110A, 110B, 110C (referred to collectively as “user devices 110”). The computing system 101 shown in FIG. 1 includes one or more servers 108, quantum computing systems 103A, 103B, a local network 109 and other resources 107. The computing system 101 may also include one or more user devices (e.g., the user device 110A) as well as other features and components. A computing system may include additional or different features, and the components of a computing system may operate as described with respect to FIG. 1 or in another manner.

The example computing system 101 can provide services to the user devices 110, for example, as a cloud-based or remote-accessed computer system, as a distributed computing resource, as a supercomputer, or another type of high-performance computing resource, or in another manner. The computing system 101 or the user devices 110 may also have access to one or more other quantum computing systems (e.g., quantum computing resources that are accessible through the wide area network 115, the local network 109 or otherwise).

The user devices 110 shown in FIG. 1 may include one or more classical processors, memory, user interfaces, communication interfaces, and other components. For instance, the user devices 110 may be implemented as laptop computers, desktop computers, smartphones, tablets, or other types of computer devices. In the example shown in FIG. 1, to access computing resources of the computing system 101, the user devices 110 send information (e.g., programs, instructions, commands, requests, input data, etc.) to the servers 108; and in response, the user devices 110 receive information (e.g., application data, output data, prompts, alerts, notifications, results, etc.) from the servers 108. The user devices 110 may access services of the computing system 101 in another manner, and the computing system 101 may expose computing resources in another manner.

In the example shown in FIG. 1, the local user device 110A operates in a local environment with the servers 108 and other elements of the computing system 101. For instance, the user device 110A may be co-located with (e.g., located within 0.5 to 1 km of) the servers 108 and possibly other elements of the computing system 101. As shown in FIG. 1, the user device 110A communicates with the servers 108 through a local data connection.

The local data connection in FIG. 1 is provided by the local network 109. For example, some or all of the servers 108, the user device 110A, the quantum computing systems 103A, 103B, and the other resources 107 may communicate with each other through the local network 109. In some implementations, the local network 109 operates as a communication channel that provides one or more low-latency communication pathways from the server 108 to the quantum computer systems 103A, 103B (or to one or more of the elements of the quantum computer systems 103A, 103B). The local network 109 can be implemented, for instance, as a wired or wireless Local Area Network, an Ethernet connection, or another type of wired or wireless connection. The local network 109 may include one or more wired or wireless routers, wireless access points (WAPs), wireless mesh nodes, switches, high-speed cables, or a combination of these and other types of local network hardware elements. In some cases, the local network 109 includes a software-defined network that provides communication among virtual resources, for example, among an array of virtual machines operating on the server 108 and possibly elsewhere.

In the example shown in FIG. 1, the remote user devices 110B, 110C operate remote from the servers 108 and other elements of the computing system 101. For instance, the user devices 110B, 110C may be located at a remote distance (e.g., more than 1 km, 10 km, 100 km, 1,000 km, 10,000 km, or farther) from the servers 108 and possibly other elements of the computing system 101. As shown in FIG. 1, each of the user devices 110B, 110C communicates with the servers 108 through a remote data connection.

The remote data connection in FIG. 1 is provided by a wide area network 115, which may include, for example, the Internet or another type of wide area communication network. In some cases, remote user devices use another type of remote data connection (e.g., satellite-based connections, a cellular network, a virtual private network, etc.) to access the servers 108. The wide area network 115 may include one or more internet servers, firewalls, service hubs, base stations, or a combination of these and other types of remote networking elements. Generally, the computing environment 100 can be accessible to any number of remote user devices.

The example servers 108 shown in FIG. 1 can manage interaction with the user devices 110 and utilization of the quantum and classical computing resources in the computing system 101. For example, based on information from the user devices 110, the servers 108 may delegate computational tasks to the quantum computing systems 103A, 103B, and the other resources 107; the servers 108 can then send information to the user devices 110 based on output data from the computational tasks performed by the quantum computing systems 103A, 103B, and the other resources 107.

As shown in FIG. 1, the servers 108 are classical computing resources that include classical processors 111 and memory 112. The servers 108 may also include one or more communication interfaces that allow the servers to communicate via the local network 109, the wide area network 115, and possibly other channels. In some implementations, the servers 108 may include a host server, an application server, a virtual server, or a combination of these and other types of servers. The servers 108 may include additional or different features, and may operate as described with respect to FIG. 1 or in another manner.

The classical processors 111 can include various kinds of apparatus, devices, and machines for processing data, including, by way of example, a microprocessor, a central processing unit (CPU), a graphics processing unit (GPU), an FPGA (field programmable gate array), an ASIC (application specific integrated circuit), or combinations of these. The memory 112 can include, for example, a random-access memory (RAM), a storage device (e.g., a writable read-only memory (ROM) or others), a hard disk, or another type of storage medium. The memory 112 can include various forms of volatile or non-volatile memory, media, and memory devices, etc.

Each of the example quantum computing systems 103A, 103B operates as a quantum computing resource in the computing system 101. The other resources 107 may include additional quantum computing resources (e.g., quantum computing systems, quantum virtual machines (QVMs) or quantum simulators) as well as classical (non-quantum) computing resources such as, for example, digital microprocessors, specialized co-processor units (e.g., graphics processing units (GPUs), cryptographic co-processors, etc.), special purpose logic circuitry (e.g., field programmable gate arrays (FPGAs), application-specific integrated circuits (ASICs), etc.), systems-on-chips (SoCs), etc., or combinations of these and other types of computing modules.

In some implementations, the servers 108 generate programs, identify appropriate computing resources (e.g., a QPU or QVM) in the computing system 101 to execute the programs, and send the programs to the identified resources for execution. For example, the servers 108 may send programs to the quantum computing system 103A, the quantum computing system 103B, or any of the other resources 107. The programs may include classical programs, quantum programs, hybrid classical/quantum programs, and may include any type of function, code, data, instruction set, etc.

In some instances, programs can be formatted as source code that can be rendered in human-readable form (e.g., as text) and can be compiled, for example, by a compiler running on the servers 108, on the quantum computing systems 103, or elsewhere. In some instances, programs can be formatted as compiled code, such as, for example, binary code (e.g., machine-level instructions) that can be executed directly by a computing resource. Each program may include instructions corresponding to computational tasks that, when performed by an appropriate computing resource, generate output data based on input data. For example, a program can include instructions formatted for a quantum computer system, a quantum virtual machine, a digital microprocessor, co-processor or other classical data processing apparatus, or another type of computing resource.

In some cases, a program may be expressed in a hardware-independent format. For example, quantum machine instructions may be provided in a quantum instruction language such as Quil, described in the publication “A Practical Quantum Instruction Set Architecture,” arXiv:1608.03355v2, dated Feb. 17, 2017, or another quantum instruction language. For instance, the quantum machine instructions may be written in a format that can be executed by a broad range of quantum processing units or quantum virtual machines. In some cases, a program may be expressed in high-level terms of quantum logic gates or quantum algorithms, in lower-level terms of fundamental qubit rotations and controlled rotations, or in another form. In some cases, a program may be expressed in terms of control signals (e.g., pulse sequences, delays, etc.) and parameters for the control signals (e.g., frequencies, phases, durations, channels, etc.). In some cases, a program may be expressed in another form or format.

In some implementations, the servers 108 include one or more compilers that convert programs between formats. For example, the servers 108 may include a compiler that converts hardware-independent instructions to binary programs for execution by the quantum computing systems 103A, 103B. In some cases, a compiler can compile a program to a format that targets a specific quantum resource in the computer system 101. For example, a compiler may generate a different binary program (e.g., from the same source code) depending on whether the program is to be executed by the quantum computing system 103A or the quantum computing system 103B.

In some cases, a compiler generates a partial binary program that can be updated, for example, based on specific parameters. For instance, if a quantum program is to be executed iteratively on a quantum computing system with varying parameters on each iteration, the compiler may generate the binary program in a format that can be updated with specific parameter values at runtime (e.g., based on feedback from a prior iteration, or otherwise). In some cases, a compiler generates a full binary program that does not need to be updated or otherwise modified for execution.

In some implementations, the servers 108 generate a schedule for executing programs, allocate computing resources in the computing system 101 according to the schedule, and delegate the programs to the allocated computing resources. The servers 108 can receive, from each computing resource, output data from the execution of each program. Based on the output data, the servers 108 may generate additional programs that are then added to the schedule, output data that is provided back to a user device 110, or perform another type of action.

In some implementations, all or part of the computing environment operates as a cloud-based quantum computing (QC) environment, and the servers 108 operate as a host system for the cloud-based QC environment. The cloud-based QC environment may include software elements that operate on both the user devices 110 and the computer system 101 and interact with each other over the wide area network 115. For example, the cloud-based QC environment may provide a remote user interface, for example, through a browser or another type of application on the user devices 110. The remote user interface may include, for example, a graphical user interface or another type of user interface that obtains input provided by a user of the cloud-based QC environment. In some cases the remote user interface includes, or has access to, one or more application programming interfaces (APIs), command line interfaces, graphical user interfaces, or other elements that expose the services of the computer system 101 to the user devices 110.

In some cases, the cloud-based QC environment may be deployed in a “serverless” computing architecture. For instance, the cloud-based QC environment may provide on-demand access to a shared pool of configurable computing resources (e.g., networks, servers, storage, applications, services, quantum computing resources, classical computing resources, etc.) that can be provisioned for requests from user devices 110. Moreover, the cloud-based computing systems 104 may include or utilize other types of computing resources, such as, for example, edge computing, fog computing, etc.

In an example implementation of a cloud-based QC environment, the servers 108 may operate as a cloud provider that dynamically manages the allocation and provisioning of physical computing resources (e.g., GPUs, CPUs, QPUs, etc.). Accordingly, the servers 108 may provide services by defining virtualized resources for each user account. For instance, the virtualized resources may be formatted as virtual machine images, virtual machines, containers, or virtualized resources that can be provisioned for a user account and configured by a user. In some cases, the cloud-based QC environment is implemented using a resource such as, for example, OPENSTACK®. OPENSTACK® is an example of a software platform for cloud-based computing, which can be used to provide virtual servers and other virtual computing resources for users.

In some cases, the server 108 stores quantum machine images (QMI) for each user account. A quantum machine image may operate as a virtual computing resource for users of the cloud-based QC environment. For example, a QMI can provide a virtualized development and execution environment to develop and run programs (e.g., quantum programs or hybrid classical/quantum programs). When a QMI operates on the server 108, the QMI may engage either of the quantum processor units 102A, 102B, and interact with a remote user device (110B or 110C) to provide a user programming environment. The QMI may operate in close physical proximity to and have a low-latency communication link with the quantum computing systems 103A, 103B. In some implementations, remote user devices connect with QMIs operating on the servers 108 through secure shell (SSH) or other protocols over the wide area network 115.

In some implementations, all or part of the computing system 101 operates as a hybrid computing environment. For example, quantum programs can be formatted as hybrid classical/quantum programs that include instructions for execution by one or more quantum computing resources and instructions for execution by one or more classical resources. The servers 108 can allocate quantum and classical computing resources in the hybrid computing environment, and delegate programs to the allocated computing resources for execution. The quantum computing resources in the hybrid environment may include, for example, one or more quantum processing units (QPUs), one or more quantum virtual machines (QVMs), one or more quantum simulators, or possibly other types of quantum resources. The classical computing resources in the hybrid environment may include, for example, one or more digital microprocessors, one or more specialized co-processor units (e.g., graphics processing units (GPUs), cryptographic co-processors, etc.), special purpose logic circuitry (e.g., field programmable gate arrays (FPGAs), application-specific integrated circuits (ASICs), etc.), systems-on-chips (SoCs), or other types of computing modules.

In some cases, the servers 108 can select the type of computing resource (e.g., quantum or classical) to execute an individual program, or part of a program, in the computing system 101. For example, the servers 108 may select a particular quantum processing unit (QPU) or other computing resource based on availability of the resource, speed of the resource, information or state capacity of the resource, a performance metric (e.g., process fidelity) of the resource, or based on a combination of these and other factors. In some cases, the servers 108 can perform load balancing, resource testing and calibration, and other types of operations to improve or optimize computing performance.

Each of the example quantum computing systems 103A, 103B shown in FIG. 1 can perform quantum computational tasks by executing quantum machine instructions (e.g., a binary program compiled for the quantum computing system). In some implementations, a quantum computing system can perform quantum computation by storing and manipulating information within quantum states of a composite quantum system. For example, qubits (i.e., quantum bits) can be stored in and represented by an effective two-level sub-manifold of a quantum coherent physical system. In some instances, quantum logic can be executed in a manner that allows large-scale entanglement within the quantum system. Control signals can manipulate the quantum states of individual qubits and the joint states of multiple qubits. In some instances, information can be read out from the composite quantum system by measuring the quantum states of the qubits. In some implementations, the quantum states of the qubits are read out by measuring the transmitted or reflected signal from auxiliary quantum devices that are coupled to individual qubits.

In some implementations, a quantum computing system can operate using gate-based models for quantum computing. For example, the qubits can be initialized in an initial state, and a quantum logic circuit comprised of a series of quantum logic gates can be applied to transform the qubits and extract measurements representing the output of the quantum computation. Individual qubits may be controlled by single-qubit quantum logic gates, and pairs of qubits may be controlled by two-qubit quantum logic gates (e.g., entangling gates that are capable of generating entanglement between the pair of qubits). In some implementations, a quantum computing system can operate using adiabatic or annealing models for quantum computing. For instance, the qubits can be initialized in an initial state, and the controlling Hamiltonian can be transformed adiabatically by adjusting control parameters to another state that can be measured to obtain an output of the quantum computation.

In some models, fault-tolerance can be achieved by applying a set of high-fidelity control and measurement operations to the qubits. For example, quantum error correcting schemes can be deployed to achieve fault-tolerant quantum computation. Other computational regimes may be used; for example, quantum computing systems may operate in non-fault-tolerant regimes. In some implementations, a quantum computing system is constructed and operated according to a scalable quantum computing architecture. For example, in some cases, the architecture can be scaled to a large number of qubits to achieve large-scale general purpose coherent quantum computing. Other architectures may be used; for example, quantum computing systems may operate in small-scale or non-scalable architectures.

The example quantum computing system 103A shown in FIG. 1 includes a quantum processing unit 102A and a control system 105A, which controls the operation of the quantum processing unit 102A. Similarly, the example quantum computing system 103B includes a quantum processing unit 102B and a control system 105B, which controls the operation of a quantum processing unit 102B. A quantum computing system may include additional or different features, and the components of a quantum computing system may operate as described with respect to FIG. 1 or in another manner.

In some instances, all or part of the quantum processing unit 102A functions as a quantum processor, a quantum memory, or another type of subsystem. In some examples, the quantum processing unit 102A includes a quantum circuit system. The quantum circuit system may include qubit devices, readout devices, and possibly other devices that are used to store and process quantum information. In some cases, the quantum processing unit 102A includes a superconducting circuit, and the qubit devices are implemented as circuit devices that include Josephson junctions, for example, in superconducting quantum interference device (SQUID) loops or other arrangements, and are controlled by radio-frequency signals, microwave signals, and bias signals delivered to the quantum processing unit 102A. In some cases, the quantum processing unit 102A includes an ion trap system, and the qubit devices are implemented as trapped ions controlled by optical signals delivered to the quantum processing unit 102A. In some cases, the quantum processing unit 102A includes a spin system, and the qubit devices are implemented as nuclear or electron spins controlled by microwave or radio-frequency signals delivered to the quantum processing unit 102A. The quantum processing unit 102A may be implemented based on another physical modality of quantum computing.

In some implementations, the example quantum processing unit 102 is a modular quantum processing unit that includes multiple quantum processing modules. For example, the quantum processing unit 102 may include a two-dimensional or three-dimensional array of quantum processing modules, and each quantum processing module may include an array of quantum circuit devices. In some cases, the quantum processing modules are supported on a common substrate, and they are interconnected through circuitry (e.g., superconducting circuitry) on the common substrate.

In some instances, each of the quantum processing modules can include a superconducting quantum integrated circuit (QuIC) that includes one or more quantum circuit devices and superconductive lines that connect the one or more quantum circuit devices. For instance, each quantum processor chip may include qubit devices, readout resonator devices, tunable-frequency coupler devices, capacitive coupler devices, or other quantum circuit devices. Each quantum processor chip may include flux bias control lines, microwave drive lines, readout signal lines, or other types of control signal lines for providing control signals to respective quantum circuit devices. In some implementations, quantum processor chips can be coupled to each other by inter-chip coupler devices in one or more cap structures. For example, a first qubit device on a first quantum processor chip may be capacitively coupled to a tunable-frequency coupler device, which is capacitively coupled to a second qubit device on a second quantum processor chip. In some implementations, the tunable-frequency coupler device resides on the first quantum processor chip. In this case, the tunable-frequency coupler device is coupled to the second qubit device through a microwave transmission line on a cap structure. In some implementations, at least a portion of a tunable-frequency coupler device resides on a cap structure. In certain implementations, a tunable-frequency coupler device includes a lossless resonator structure. For example, a lossless resonator structure of a tunable-frequency coupler device may include a superconducting circuit loop and a shunt capacitor. In some cases, a portion of the shunt capacitor (e.g., one capacitor electrode) in the tunable-frequency coupler device may reside on the cap structure.

In some implementations, a cap structure and a quantum processor chip in a modular quantum processing unit 102A are bonded together, for example, by bonding bumps or another type of bond. In some instances, the cap structure contains one or more recesses, each defined by a recessed surface and sidewalls. When a cap structure and a quantum processor chip are bonded together, a recess on the cap structure can house a qubit device on the quantum processor chip. The cap structure may also contain various superconducting circuitry. Circuitry may include a variety of superconducting circuit elements to control or readout quantum circuit devices (e.g., qubit devices). For instance, circuitry on a cap structure may include coupling lines, microwave drive lines, microwave feedlines, flux bias lines, tunable-frequency coupler devices, or other circuit elements. In some instances, a cap structure may be communicably coupled to the control system 105, e.g., to receive control signals or transmit readout signals.

The quantum processing unit 102A may include, or may be deployed within, a controlled environment. The controlled environment can be provided, for example, by shielding equipment, cryogenic equipment, and other types of environmental control systems. In some examples, the components in the quantum processing unit 102A operate in a cryogenic temperature regime and are subject to very low electromagnetic and thermal noise. For example, magnetic shielding can be used to shield the system components from stray magnetic fields, optical shielding can be used to shield the system components from optical noise, and thermal shielding and cryogenic equipment can be used to maintain the system components at controlled temperature, etc.

In some implementations, the example quantum processing unit 102A can process quantum information by applying control signals to the quantum circuit devices in the quantum processing unit 102A. The control signals can be configured to encode information in the qubits, to process the information by performing quantum logic gates or other types of operations, or to extract information from the qubits. In some examples, the operations can be expressed as single-qubit quantum logic gates, two-qubit quantum logic gates, or other types of quantum logic gates that operate on one or more qubits. A quantum logic circuit, which includes a sequence of quantum logic operations, can be applied to the qubits to perform a quantum algorithm. The quantum algorithm may correspond to a computational task, a hardware test, a quantum error correction procedure, a quantum state distillation procedure, or a combination of these and other types of operations.

The example control system 105A includes controllers 106A and signal hardware 104A. Similarly, control system 105B includes controllers 106B and signal hardware 104B. All or part of the control systems 105A, 105B can operate in a room-temperature environment or another type of environment, which may be located near the respective quantum processing units 102A, 102B. In some cases, the control systems 105A, 105B include classical computers, signaling equipment (microwave, radio, optical, bias, etc.), electronic systems, vacuum control systems, refrigerant control systems, or other types of control systems that support operation of the quantum processing units 102A, 102B.

The control systems 105A, 105B may be implemented as distinct systems that operate independent of each other. In some cases, the control systems 105A, 105B may include one or more shared elements; for example, the control systems 105A, 105B may operate as a single control system that operates both quantum processing units 102A, 102B. Moreover, a single quantum computer system may include multiple quantum processing units, which may operate in the same controlled (e.g., cryogenic) environment or in separate environments.

The example signal hardware 104A includes components that communicate with the quantum processing unit 102A. The signal hardware 104A may include, for example, waveform generators, amplifiers, digitizers, high-frequency sources, DC sources, AC sources, etc. The signal hardware may include additional or different features and components. In the example shown, components of the signal hardware 104A are adapted to interact with the quantum processing unit 102A. For example, the signal hardware 104A can be configured to operate in a particular frequency range, configured to generate and process signals in a particular format, or the hardware may be adapted in another manner.

In some instances, one or more components of the signal hardware 104A generate control signals, for example, based on control information from the controllers 106A. The control signals can be delivered to the quantum processing unit 102A during operation of the quantum computing system 103A. For instance, the signal hardware 104A may generate signals to implement quantum logic operations, readout operations, or other types of operations. As an example, the signal hardware 104A may include arbitrary waveform generators (AWGs) that generate electromagnetic waveforms (e.g., microwave or radio-frequency) or laser systems that generate optical waveforms. The waveforms or other types of signals generated by the signal hardware 104A can be delivered to devices in the quantum processing unit 102A to operate qubit devices, readout devices, bias devices, coupler devices, or other types of components in the quantum processing unit 102A.

In some instances, the signal hardware 104A receives and processes signals from the quantum processing unit 102A. The received signals can be generated by the execution of a quantum program on the quantum computing system 103A. For instance, the signal hardware 104A may receive signals from the devices in the quantum processing unit 102A in response to readout or other operations performed by the quantum processing unit 102A. Signals received from the quantum processing unit 102A can be mixed, digitized, filtered, or otherwise processed by the signal hardware 104A to extract information, and the information extracted can be provided to the controllers 106A or handled in another manner. In some examples, the signal hardware 104A may include a digitizer that digitizes electromagnetic waveforms (e.g., microwave or radio-frequency) or optical signals, and a digitized waveform can be delivered to the controllers 106A or to other signal hardware components. In some instances, the controllers 106A process the information from the signal hardware 104A and provide feedback to the signal hardware 104A; based on the feedback, the signal hardware 104A can in turn generate new control signals that are delivered to the quantum processing unit 102A.

In some implementations, the signal hardware 104A includes signal delivery hardware that interfaces with the quantum processing unit 102A. For example, the signal hardware 104A may include filters, attenuators, directional couplers, multiplexers, diplexers, bias components, signal channels, isolators, amplifiers, power dividers, and other types of components. In some instances, the signal delivery hardware performs preprocessing, signal conditioning, or other operations to the control signals to be delivered to the quantum processing unit 102A. In some instances, signal delivery hardware performs preprocessing, signal conditioning, or other operations on readout signals received from the quantum processing unit 102A.

The example controllers 106A communicate with the signal hardware 104A to control operation of the quantum computing system 103A. The controllers 106A may include classical computing hardware that directly interface with components of the signal hardware 104A. The example controllers 106A may include classical processors, memory, clocks, digital circuitry, analog circuitry, and other types of systems or subsystems. The classical processors may include one or more single- or multi-core microprocessors, digital electronic controllers, special purpose logic circuitry, e.g., an FPGA (field programmable gate array) or an ASIC (application specific integrated circuit), or other types of data processing apparatus. The memory may include any type of volatile or non-volatile memory or another type of computer storage medium. The controllers 106A may also include one or more communication interfaces that allow the controllers 106A to communicate via the local network 109 and possibly other channels. The controllers 106A may include additional or different features and components.

In some implementations, the controllers 106A include memory or other components that store quantum state information, for example, based on qubit readout operations performed by the quantum computing system 103A. For instance, the states of one or more qubits in the quantum processing unit 102A can be measured by qubit readout operations, and the measured state information can be stored in a cache or other type of memory system in or more of the controllers 106A. In some cases, the measured state information is subsequently used in the execution of a quantum program, a quantum error correction procedure, a quantum processing unit (QPU) calibration or testing procedure, or another type of quantum process.

In some implementations, the controllers 106A include memory or other components that store a quantum program containing quantum machine instructions for execution by the quantum computing system 103A. In some instances, the controllers 106A can interpret the quantum machine instructions and perform hardware-specific control operations according to the quantum machine instructions. For example, the controllers 106A may cause the signal hardware 104A to generate control signals that are delivered to the quantum processing unit 102A to execute the quantum machine instructions.

In some instances, the controllers 106A extract qubit state information from qubit readout signals, for example, to identify the quantum states of qubits in the quantum processing unit 102A or for other purposes. For example, the controllers may receive the qubit readout signals (e.g., in the form of analog waveforms) from the signal hardware 104A, digitize the qubit readout signals, and extract qubit state information from the digitized signals. In some cases, the controllers 106A compute measurement statistics based on qubit state information from multiple shots of a quantum program. For example, each shot may produce a bitstring representing qubit state measurements for a single execution of the quantum program, and a collection of bitstrings from multiple shots may be analyzed to compute quantum state probabilities.

In some implementations, the controllers 106A include one or more clocks that control the timing of operations. For example, operations performed by the controllers 106A may be scheduled for execution over a series of clock cycles, and clock signals from one or more clocks can be used to control the relative timing of each operation or groups of operations. In some implementations, the controllers 106A may include classical computer resources that perform some or all of the operations of the servers 108 described above. For example, the controllers 106A may operate a compiler to generate binary programs (e.g., full or partial binary programs) from source code; the controllers 106A may include an optimizer that performs classical computational tasks of a hybrid classical/quantum program; the controllers 106A may update binary programs (e.g., at runtime) to include new parameters based on an output of the optimizer, etc.

The other quantum computer system 103B and its components (e.g., the quantum processing unit 102B, the signal hardware 104B and controllers 106B) can be implemented as described above with respect to the quantum computer system 103A; in some cases, the quantum computer system 103B and its components may be implemented or may operate in another manner.

In some implementations, the quantum computer systems 103A, 103B are disparate systems that provide distinct modalities of quantum computation. For example, the computer system 101 may include both an adiabatic quantum computer system and a gate-based quantum computer system. As another example, the computer system 101 may include a superconducting circuit-based quantum computer system and an ion trap-based quantum computer system. In such cases, the computer system 101 may utilize each quantum computing system according to the type of quantum program that is being executed, according to availability or capacity, or based on other considerations.

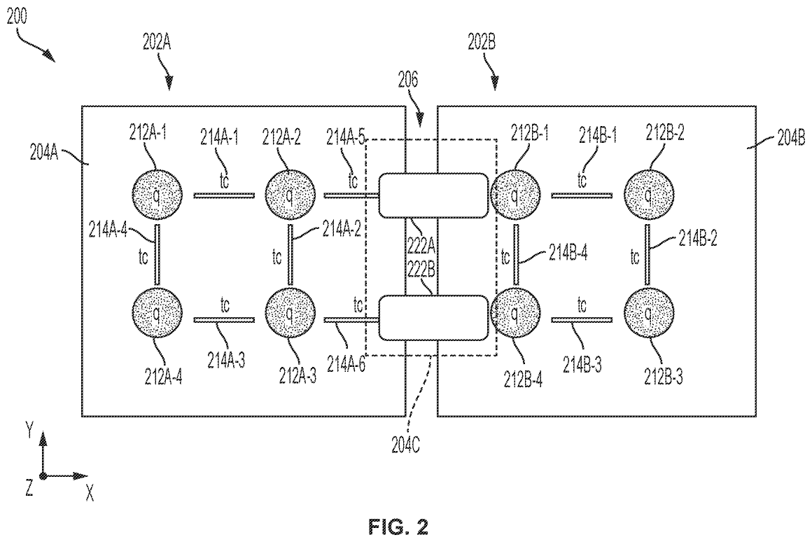

FIG. 2 is a schematic diagram showing aspects of a top view of an example modular quantum processing unit 200. The example modular quantum processing unit 200 includes two quantum processor chips 202A, 202B. The two quantum processor chips 202A, 202B are bonded to a cap structure 206 so that certain quantum circuit devices on the two quantum processor chips 202A, 202B can be interconnected by inter-chip coupler devices 222 on the cap structure 206. Each of the two quantum processor chips 202A, 202B includes a superconducting quantum integrated circuit (QuIC). The superconducting QuIC can include quantum circuit devices, for example, qubit devices 212 (e.g., transmon devices, fluxonium devices, or other types of superconducting qubit devices), coupler devices (e.g., capacitive coupler device, tunable-frequency coupler device, or others), readout devices, or other types of quantum circuit devices that are used for quantum information processing in the modular quantum processing unit 200. The superconducting QuIC of each of the two quantum processor chips 202A, 202B may include one or more Josephson junctions, capacitors, inductors, and other types of circuit elements. In some implementations, the example modular quantum processing unit 200 may include additional and different features or components, and components of the example modular quantum processing unit 200 may be implemented in another manner.

As shown in the example modular quantum processing unit 200, the first quantum processor chip 202A includes a first substrate 204A; and the second quantum processor chip 202B includes a second substrate 204B. The first substrate 204A supports the superconducting QuIC of the first quantum processor chip 202A; and the second substrate 204B supports the superconducting QuIC of the second quantum processor chip 202B. In certain examples, the cap structure 206 includes a third substrate 204C. In this case, the third substrate 204C supports the inter-chip coupler devices 222 and other superconducting circuit elements of the cap structure 206. In some implementations, the example modular quantum processing unit 200 may include more than two quantum processor chips 202 on multiple dies/substrates bonded to the cap structure 206 on the same side or on the opposite side through the superconducting circuitry on the cap structure 206.

In some implementations, the first and second substrates 204A, 204B may include a dielectric substrate (e.g., silicon, sapphire, etc.). In certain examples, the first and second substrates 203, 213 may include an elemental semiconductor material such as, for example, silicon (Si), germanium (Ge), selenium (Se), tellurium (Te), or another elemental semiconductor. In some instances, the first and second substrates 204A, 204B may also include a compound semiconductor such as silicon germanium (SiGe), silicon carbide (SiC), silicon germanium carbide (SiGeC), aluminum oxide (sapphire), gallium arsenide (GaAs), indium arsenide (InAs), indium phosphide (InP), gallium arsenic phosphide (GaAsP), or gallium indium phosphide (GalnP). In some instances, the first and second substrates 204A, 204B may also include a superlattice with elemental or compound semiconductor layers. In some instances, the first and second substrates 204A, 204B include an epitaxial layer. In some examples, the first and second substrates 204A, 204B may have an epitaxial layer overlying a bulk semiconductor or may include a semiconductor-on-insulator (SOI) structure. In some instances, the third substrate 204C of the cap structure 206 may be implemented as the first and second substrates 204A, 204B or another substrate.

The superconducting QuIC on each of the quantum processor chips 202A, 202B and the superconducting circuitry on the cap structure 206 include superconducting materials. In some implementations, the superconducting materials may be superconducting metals, such as aluminum (Al), niobium (Nb), tantalum (Ta), vanadium (V), tungsten (W), indium (In), titanium (Ti), Lanthanum (La), lead (Pb), tin (Sn), and/or zirconium (Zr), that are superconducting at an operating temperature of the example modular quantum processing unit 200, or another superconducting metal. In some implementations, the superconducting materials may include superconducting metal alloys, such as molybdenum-rhenium (Mo/Re), niobium-tin (Nb/Sn), or another superconducting metal alloy. In some implementations, the superconducting materials may include superconducting compound materials, including superconducting metal nitrides and superconducting metal oxides, such as titanium-nitride (TiN), niobium-nitride (NbN), zirconium-nitride (ZrN), hafnium-nitride (HfN), vanadium-nitride (VN), tantalum-nitride (TaN), molybdenum-nitride (MoN), yttrium barium copper oxide (Y—Ba—Cu—O), or another superconducting compound material. In some instances, the superconducting materials may include multilayer superconductor-insulator heterostructures.

In some implementations, the superconducting QuIC on each of the quantum processor chips 202A, 202B and the superconducting circuitry on the cap structure 206 (e.g., the inter-chip coupler devices 222) can be formed on surfaces of the substrates 204A, 204B, 204C and patterned using a microfabrication process or in another manner. For example, the superconducting QuIC on each of the quantum processor chips 202A, 202B and the superconducting circuitry (including the inter-chip coupler devices 222A, 222B) on the cap structure 206 may be formed by performing at least some of the following fabrication processes: using chemical vapor deposition (CVD), physical vapor deposition (PVD), atomic layer deposition (ALD), and/or other suitable techniques to deposit respective superconducting layers on the substrates 204A, 204B, 204C; and performing one or more patterning processes (e.g., a lithography process, a dry/wet etching process, a soft/hard baking process, a cleaning process, etc.) to form openings in the respective superconducting layers.

In the example shown in FIG. 2, the qubit devices 212 in the superconducting QuIC of the quantum processor chips 202 are arranged in a rectilinear (e.g., rectangular, or square) array that extends in two spatial dimensions (e.g., in the plane of the page). In some implementations, the qubit devices 212 can be arranged in another type of ordered array. In some instances, the rectilinear array also extends in a third spatial dimension (e.g., in/out of the page), for example, to form a cubic array or another type of three-dimensional array.

In the example shown in FIG. 2, each of the quantum processor chips 202A, 202B of the example modular quantum processing unit 200 includes four qubit devices 212. In some examples, the qubit frequency of a qubit device is not tunable by application of an offset field and is independent of magnetic flux experienced by the qubit device. For instance, a fixed-frequency qubit device may have a fixed qubit frequency that is defined by an electronic circuit of the qubit device. As an example, a superconducting fixed-frequency qubit device (e.g., a fixed-frequency transmon qubit device) may be implemented without a SQUID (Superconducting Quantum Interference Device) loop. In some examples, the qubit frequency of a qubit device 212 in a superconducting QuIC of a quantum processor chip 202 is tunable, for example, by application of an offset field. For instance, a superconducting tunable-frequency qubit device may include a superconducting circuit loop (e.g., a SQUID loop), which can receive a magnetic flux that tunes the qubit frequency of the tunable-frequency qubit device. In this case, the superconducting QuIC of the quantum process modules 202A, 202B may include flux bias control lines for tuning the magnetic flux through the SQUID loops of the qubit devices 212. In some instances, the superconducting QuIC of the quantum process modules 202A, 202B includes drive signal lines that are configured to communicate microwave control signals to the qubit devices 212. The superconducting QuIC of the quantum processor chips 202A, 202B may include additional devices, including additional qubit devices, readout resonators, or other quantum circuit devices.

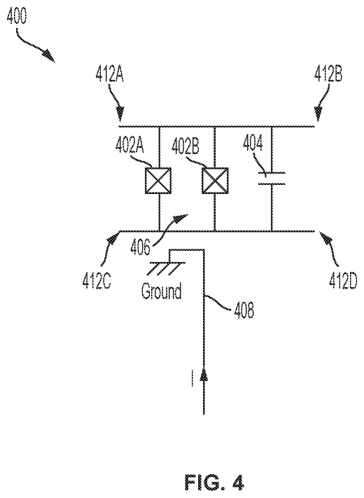

In some implementations, the superconducting QuIC of each of the quantum processor chips 202A, 202B includes tunable-frequency coupler devices 214. Each of the tunable-frequency coupler devices 214 may be implemented as a tunable-frequency transmon qubit device or another type of tunable-frequency qubit device. In this case, each of the tunable-frequency coupler devices 214 includes two Josephson junctions connected in parallel with each other to form a SQUID loop, which resides adjacent to a control signal line (e.g., a flux-bias control line). The tunable-frequency coupler device 214 further includes a shunt capacitor. In some implementations, the shunt capacitor is connected with the two Josephson junctions in parallel creating a lossless resonator structure of the tunable-frequency coupler device 214. In some implementations, a tunable-frequency coupler device 214 may be implemented as the example tunable-frequency coupler device 400 shown in FIG. 4 or in another manner. A tunable-frequency coupler device 214 in the quantum processor chips 202A, 202B may include another type of lossless resonator structure.

In some implementations, a tunable-frequency coupler device 214 controls the interaction between two qubit devices 212. For example, a capacitive coupling between the two qubit devices can be tuned to a value close to zero. In this case, the capacitive coupling between the two qubit devices is deactivated. In some instances, the capacitive coupling between the two qubit devices can be tuned to a designed value (e.g., a gate-activating value), for example, during two-qubit quantum logic gate operations allowing qubit-qubit coupling. In some implementations, the superconducting circuit loop (e.g., the SQUID loop) of the tunable-frequency coupler device 214 can receive a magnetic flux ¢(t) that controls the operating frequency of the tunable-frequency coupler device 214. Manipulating the magnetic flux @(t) through the superconducting circuit loop can increase or decrease the operating frequencies of the tunable-frequency coupler device 214. In this example, the magnetic flux ¢(t) through the superconducting circuit loop is an offset field that can be modified in order to tune the operating frequencies of the tunable-frequency coupler device 214. In some cases, inductors or other types of flux bias devices as part of flux bias control lines carrying the control signals are coupled to the superconducting circuit loop by a mutual inductance, and the magnetic flux ¢(t) through the superconducting circuit loop can be controlled by the current through the inductors.

In some implementations, the tunable-frequency coupler device 214 resides between two neighboring qubit devices and is capacitively coupled to each of the two neighboring qubit devices 212 through two respective capacitive coupler devices (e.g., the capacitive coupler devices 318A, 318B as shown in FIG. 3D). By tuning the qubit frequency of the tunable-frequency coupler device 214, the coupling between the tunable-frequency coupler device 214 and each of the two neighboring qubit devices 212 on the same quantum processor chip 202, and thus, the coupling between the two qubit devices 212, can be tuned. In some implementations, a qubit frequency of the tunable-frequency coupler device 214 may be defined at least in part by the Josephson energy of the Josephson junctions in the circuit loop, a capacitance of the shunt capacitor, and a magnetic flux threading the circuit loop.

In some implementations, the superconducting QuIC of the quantum processor chips 202A, 202B includes control signal lines for at least controlling the tunable-frequency coupler devices 214. In some aspects of operation, control signals can be transmitted to the tunable-frequency coupler devices 214 in the quantum processor chip 202, for example, from an external control system (e.g., the control system 105 of FIG. 1). The control signals can be configured to modulate, increase, decrease, or otherwise manipulate the qubit frequencies of the tunable-frequency coupler devices 214. For example, the control signal can be a flux bias control signal that varies a magnetic flux experienced by the tunable-frequency coupler device 214, and varying the magnetic flux can change the qubit frequency of the tunable-frequency coupler device 214. In some instances, the control signal line can include, for example, a flux bias device that is configured to apply an offset magnetic field to the tunable-frequency coupler device 214. For instance, the flux bias device may include an inductor that has a mutual inductance with the circuit loop of the tunable-frequency coupler device 214.

In some implementations, a control signal can be a direct current (DC) signal communicated, for example, from the control system to the individual tunable-frequency coupler device on a quantum processor chip 202. In some implementations, a control signal can be an alternating current (AC) signal communicated to the individual tunable-frequency coupler device. In some cases, the AC signal may be superposed with a direct current (DC) signal. Other types of control signals may be used. In some implementations, the effective coupling between two neighboring qubit devices 212 can be controlled or actuated by tuning a magnetic field applied to the tunable-frequency coupler device 214 residing between the two neighboring qubit devices 212. For example, a control signal (e.g., a DC or an AC current) can be applied to a control signal line to tune the magnetic flux threading to the circuit loop of the tunable-frequency coupler device 214 to turn on or off the coupling. In some implementations, control signal lines for tuning the magnetic field in the tunable-frequency coupler device 214 on the quantum processor chip 212 can be supported on the same substrate as the SQUID loop of the tunable-frequency coupler device 214, for example, on the surface of the first or second substrate 204A, 204B. In some implementations, the control signal lines for tuning the magnetic field in the SQUID loop of the tunable-frequency coupler device 214 on the quantum processor chip 212 can be supported on the cap structure 206.

As shown in FIG. 2, the inter-chip coupler devices 222A, 222B may reside on the same cap structure 206. In some instances, the inter-chip coupler devices 222A, 222B reside on separate cap structures. As shown in FIG. 2, the inter-chip coupler device 222A is configured to provide inter-chip coupling between the tunable-frequency coupler device 214A-5 on the first quantum processor chip 202A and the qubit device 212B-1 on the second quantum processor chip 202B; and the inter-chip coupler device 222B is configured to provide inter-chip coupling between the tunable-frequency coupler device 214A-6 on the first quantum processor chip 202A and the qubit device 212B-4 on the second quantum processor chip 202B.

In some implementations, each of the inter-chip coupler devices 222A, 222B includes a planar microwave transmission line, for example coplanar waveguides, substrate integrated waveguides, or another type of planar transmission line structure. As shown in FIG. 2, the inter-chip coupler device 222A is coupled to the tunable-frequency coupler device 214A-5 on the first quantum processor chip 202A and to the qubit device 212B-1 on the second quantum processor chip 202B. Connections between the inter-chip coupler device 222A and the tunable-frequency coupler device 214A-5 and the qubit device 212B-1 can be galvanic, for example through superconductive contacts (e.g., indium bumps and contact electrodes) or capacitive through parallel capacitor electrodes. Thus, the inter-chip coupler devices 222A, 222B are galvanically or capacitively coupled to the quantum processor chips 202A, 202B allowing microwave signals to propagate between the two quantum processor chips 202A, 202B. In this case, the qubit device 212A-2 on the first quantum processor chip 202A can be communicably coupled to the qubit device 212B-1 on the second quantum processor chip 202B through the inter-chip coupler device 222A, when the tunable-frequency coupler device 214A-5 on the first quantum processor chip 202A is turned on. By operating the tunable-frequency coupler device 214A-5, information stored in the qubit device 212A-2 on the first quantum processor chip 202A and stored in the qubit device 212B-1 on the second quantum processor chip 202B can be processed by selectively coupling the two qubit devices 212A-2 and 212B-1 from two separate quantum processor chips.

In some implementations, the cap structure 206 is bonded to the first and second quantum processor chips 202A, 202B through superconductive contacts. In some instances, the superconducting contacts can improve the shielding of the quantum circuit devices (e.g., the qubit devices 212 and the tunable-frequency coupler devices 214) on the quantum processor chips 202A, 202B by creating a Faraday cage around the quantum circuit devices. In certain instances, the superconducting contacts can reduce cross talk between qubit devices and their control signal lines.

In some implementations, a cap structure 206 further includes through-hole conductive vias that connect top and bottom surfaces of the third substrate 204C. In some implementations, the through-hole conductive vias include a material (e.g., Al, In, Ti, Pn, Sn, etc.) that is superconducting at an operating temperature of the example modular quantum processing unit 200. In some implementations, the through-hole conductive vias can be used to form a continuous ground plane through the example modular quantum processing unit 200, such that a solidly connected ground plane can be maintained across both the modular quantum processor chips 202 and the cap structure 206 (e.g., the interconnected ground planes 320C and 320D in FIGS. 3A-3D, 620C, and 620D in FIGS. 6, and 720C, 720D in FIG. 7).

In some instances, through-hole conductive vias may be arranged in a regular array to avoid a formation of a chip-mode resonance and to mitigate unwanted modes (e.g., coupled slotline mode, parallel-plate waveguide modes, or resonant patch mode). For example, such a regular array of through-hole conductive vias connected to the ground planes can push dielectric chip modes with the cap structure to higher frequencies. In some implementations, a subset of the one or more through-hole conductive vias are electrically coupled with external signal lines, which are used to supply control signals to, or retrieve readout signals from, the quantum circuit devices of the quantum processor chips 202A, 202B. In some instances, the one or more through-hole conductive vias may include another subset that can be used for thermalization. In this case, the cap structure 206 allows better heatsinking of the quantum circuit devices to the refrigeration system using the one or more through-hole conductive vias as thermal paths for heat dissipation.

In some instances, through-hole vias can be used as a part of circuit components of tunable-frequency coupler devices 214. For example, a tunable-frequency coupler device 214 may include a shunt capacitor with a capacitor structure formed in a through-hole via on the first substrate 204A. For another example, a tunable-frequency coupler device 214 may include a superconducting circuit loop with a conductor in a form of a through-hole conductive via.

In some implementations, the inter-chip coupler devices 222A, 222B in the cap structure 206 include a quantum bus architecture. In this case, the tunable-frequency coupler devices can be used to selectively provide inter-chip coupling between different qubit devices on different quantum processor chips. For example, multiple qubit devices can be coupled to a quantum bus (e.g., a common microwave transmission line) on the cap structure via corresponding tunable-frequency coupler devices. Two or more qubit devices can be coupled by the quantum bus by selectively operating the corresponding tunable-frequency coupler devices which act as gates. In some instances, the tunable-frequency coupler devices and the quantum bus (e.g., the common microwave transmission line) can be supported on the same cap structure.

In some instances, the cap structure 206 can be bonded to the quantum processor chips 202A, 202B using bonding bumps. In some implementations, each of the bonding bumps may include conductive or superconductive materials, such as copper or indium bumps. In some implementations, the bonding bumps can provide electrical communication of the superconducting QuIC of the quantum processor chips 202A, 202B with the superconducting circuitry (e.g., the inter-chip coupler device 222A, 222B) on the cap structure 206. The gap separating the cap structure 206 and the quantum processor chips 202A, 202B is determined by the height of the bonding bumps. In some instances, superconducting bonding bumps can be selectively structured between the surface of the cap structure 206 and the surface of the quantum processor chips 202A, 202B to segment the ground plane. Segments of the ground plane, which, for example, can be kept at an equipotential, can control the flow of supercurrent to prevent flux currents from intermingling.

In some instances, the cap structure 206 includes recesses that house respective qubit devices 212 or tunable-frequency coupler devices 214 on the quantum processor chip 202 when being bonded to the quantum processor chips 202. Each of the recesses includes a recessed surface and sidewalls. In some instances, the recessed surface and sidewalls can include conductive materials which can be used as a Faraday cage to prevent stray electric fields from reaching the quantum circuit devices housed by the recess. In certain examples, when the conductive materials include superconducting materials, stray magnetic fields can be excluded from reaching the quantum circuit devices housed by recesses.

In some implementations, the cap structure 206 may include a variety of circuit elements to control or readout the qubit devices 212 and the tunable-frequency coupler devices 214. For example, the cap structure 206 may include flux bias control lines which can provide magnetic flux locally to tunable-frequency qubit devices or tunable-frequency coupler devices to tune their frequencies. The cap structure 206 may also include resonator devices which are capacitively coupled to qubit devices to readout qubits. In some examples, the cap structure 206 may include microwave feedlines which are coupled to one or several of the resonator devices to allow microwave excitation of the resonator devices used to readout qubits of qubit devices. The cap structure 206 may include microwave drive lines which are capacitively coupled to qubit devices to drive qubits. The cap structure 206 may further include filters, isolators, circulators, amplifiers, or other circuit elements.

In some implementations, the first and second quantum processor chips 202A, 202B are supported on a common substrate. The common substrate includes signal lines that are configured to communicate signals between qubit devices and an external control system (e.g., the control system 105 in FIG. 1). In some instances, a common substrate may include signal convertor devices that receive first control signals in a different regium (e.g., an optical frequency range) from the external control system, convert to second control signals in a microwave frequency range, and further transmit the second control signals to qubit devices. In some instances, the signal converter devices on the common substrate can also receive first readout signals in the microwave frequency range from qubit devices, convert to second readout signals in a different frequency range (e.g., in an optical frequency range), and transmit the second readout signals to the external control system.

FIGS. 3A-3D are equivalent circuit diagrams of example modular quantum processing units 300A, 300B, 300C, 300D. The example modular quantum processing units 300A, 300B, 300C, 300D in FIGS. 3A-3D include a first quantum processor chip 302A, a second quantum processor chip 302B, and a cap structure 304. The first quantum processor chip 302A and the second quantum processor chip 302B can be implemented, for instance, as the first and second quantum processor chips 202A, 202B in FIG. 2 or in another manner. The first quantum processor chip 302A includes a first qubit device 312A, which can be implemented as the qubit device 212A-2, 212A-3 on the first quantum processor chip 202A in FIG. 2. Similarly, the second quantum processor chip 302B includes a second qubit device 312B, which may be implemented as the qubit device 212B-1, 212B-4 on the second quantum processor chip 202B in FIG. 2. The first quantum processor chip 302A and the second quantum processor chip 302B may include multiple qubit devices which may be arranged as the array shown in FIG. 2 or in another manner.

As shown in FIGS. 3A-3D, the first quantum processor chip 302A further includes a tunable-frequency coupler device 314 which is capacitively coupled to the first qubit device 312A through a capacitive coupler device 318A. In some instances, the tunable-frequency coupler device 314 resides on the same surface as the first qubit device 312A on the first quantum processor chip 302A. In certain instances, the capacitive coupler device 318A, which is configured to provide a fixed capacitive coupling between the tunable-frequency coupler device 314 and the first qubit device 312A, may be implemented as a microstrip capacitor with two overlapping arms between neighboring qubit electrodes of the qubit device 312A and the tunable-frequency coupler device 314; or the capacitive coupler device 318A may have another type of structure.

In some instances, the tunable-frequency coupler device 314 includes a lossless resonator structure. In the example shown, the tunable-frequency coupler device 314 includes a superconducting circuit loop (e.g., a SQUID loop) and a shunt capacitor. In certain examples, the tunable-frequency coupler device 314 may be implemented as the example tunable-frequency coupler device 400 in FIG. 4. In certain instances, the tunable-frequency coupler device 314 may include other circuit elements, for example, circuit elements that are configured in another manner to form the lossless resonator structure.

As shown in FIGS. 3A-3D, the cap structure 304 includes an inter-chip coupler device 322. In some implementations, the inter-chip coupler device 322 on the cap structure 304 is configured to provide inter-chip coupling between quantum circuit devices on different quantum processor chips 302A, 302B. In particular, the inter-chip coupler device 322 may be coupled to the tunable-frequency coupler device 314 on a first end, and coupled to the second qubit device 312B on a second end. The inter-chip coupler device 322 may be implemented as the inter-chip coupler device 222A, 222B as shown in FIG. 2 or in another manner. In the example shown in FIGS. 3A-3D, the inter-chip coupler device 322 is a microwave transmission line (e.g., a coplanar waveguide, a substrate integrated waveguide, or another type of planar transmission line). FIGS. 3A-3D show different examples of connections between the inter-chip coupler device 322 and the tunable-frequency coupler device 314 on the first quantum processor chip 302A and connections between the inter-chip coupler device 322 and the second qubit device 312B on the second quantum processor chip 302B.

As shown in FIG. 3A, the first end of the inter-chip coupler device 322 on the cap structure 304 is capacitively coupled to the tunable-frequency coupler device 314 on the first quantum processor chip 302A, e.g., forming a first capacitive connection 320A; and the second end of the inter-chip coupler device 322 on the cap structure 304 is capacitively coupled to the second qubit device 312B on the second quantum processor chip 302B, e.g., forming a second capacitive connection 320B. The capacitive connections 320A, 320B allow the tunable-frequency coupler device 314 on the first quantum processor chip 302A to be capacitively coupled to the second qubit device 312B on the second quantum processor chip 302B. In some implementations, each of the capacitive connections 320A, 320B includes two capacitor electrodes. In some instances, one of the capacitor electrodes in the first and second capacitive connections 320A, 320B is on the surface of the cap structure 304 and the other capacitor electrode in the first and second capacitive connections 320A, 320B is on the surface of the first or second quantum processor chips 302A, 302B. The two capacitor electrodes in a capacitive connection, when the cap structure 304 is bonded to the first and second quantum process modules 302A, 302B, are separated by a gap (e.g., a vacuum gap).

The first qubit device 312A, the tunable-frequency coupler device 314, and other superconducting circuit elements in the superconducting QuIC of the first quantum processor chip 302A (e.g., the first capacitive coupler device 318A, superconductive lines, and the capacitor electrode) reside on the surface of a first substrate 306A; the second qubit device 312B and other superconducting circuit elements in the superconducting QuIC of the second quantum processor chip 302B reside on the surface of a second substrate 306B. The first and second substrates 306A, 306B may be implemented as the substrates 204A, 204B in FIG. 2 or in another manner. The inter-chip coupler device 322 and other superconducting circuit element in the superconductive circuitry of the cap structure 304 reside on the surface of a third substrate 308, which may be implemented as the third substrate 204C in FIG. 2.

As shown in FIGS. 3A-3D, ground planes of the first and second quantum processor chips 302A, 302B, and the cap structure 304 are galvanically connected forming a universal ground plane across the modular quantum processing unit 300A, 300B, 300C, 300D through galvanic connections 320C, 320D. In some instances, the galvanic connections 320C, 320D may be formed by superconductive bonding bumps and contact electrodes when the cap structure 304 is bonded to the first and second quantum processor chips 302A, 302B.

As shown in FIG. 3B, the first end of the inter-chip coupler device 322 on the cap structure 304 is capacitively coupled to the tunable-frequency coupler device 314 on the first quantum processor chip 302A, e.g., forming a capacitive connection 330A; and the second end of the inter-chip coupler device 322 on the cap structure 304 is galvanically coupled to the second qubit device 312B on the second quantum processor chip 302B, e.g., forming a galvanic connection 330B. In some examples, the capacitive connection 330A can be implemented as the capacitive connection 320A, 320B in FIG. 3B, or in another manner; and the galvanic connection 330B may be implemented as the galvanic connections 320C, 320D, or in another manner.

As shown in FIG. 3C, the first end of the inter-chip coupler device 322 on the cap structure 304 is galvanically coupled to the tunable-frequency coupler device 314 on the first quantum processor chip 302A, e.g., forming a galvanic connection 340A; and the second end of the inter-chip coupler device 322 on the cap structure 304 is capacitively coupled to the second qubit device 312B on the second quantum processor chip 302B, e.g., forming a capacitive connection 340B. In some examples, the capacitive connection 340B can be implemented as the capacitive connection 320A, 320B in FIG. 3A, 330A in FIG. 3B, or in another manner; and the galvanic connection 340A may be implemented as the galvanic connections 320C, 320D in FIGS. 3A-3D, 330B in FIG. 3B, or in another manner.

As shown in FIG. 3D, the second quantum processor chip 302B further includes a second capacitive coupling device 318B. In this case, the first end of the inter-chip coupler device 322 on the cap structure 304 is galvanically coupled to the tunable-frequency coupler device 314 on the first quantum processor chip 302A, e.g., forming a first galvanic connection 350A; and the second end of the inter-chip coupler device 322 on the cap structure 304 is galvanically coupled to the second capacitive coupler device 318B on the second quantum processor chip 302B, e.g., forming a second galvanic connection 350B. In some examples, each of the first and second galvanic connections 350A, 350B can be implemented as the galvanic connections 320C, 320D in FIGS. 3A-3D, or in another manner. In this case, during operation, the tunable-frequency coupler device 314 on the first quantum processor chip 302A can be capacitively coupled to the second qubit device 312B through the second capacitive coupler device 318B. In certain examples, the second capacitive coupler device 318B may be implemented as the first capacitive coupler device 318A, or in another manner, providing a fixed capacitive coupling to the second qubit device 312B.

In some implementations, control operations can be performed on the superconducting circuit by providing control signals to the tunable-frequency coupler device 314 via control signal lines. The control signal lines can receive the control signals, for example, from an external control system (e.g., the control system 105 in FIG. 1). In some implementations, each of the control signal lines can be a conductor, an inductor, or another type of circuit component configured to carry a respective current I, which generates a respective magnetic flux ¢(t) through the superconducting circuit loop of the tunable-frequency coupler device 314. In the example shown, the transition frequency of the tunable-frequency coupler device 314 is tuned by tuning a magnetic flux in the superconducting circuit loop. In some instances, the transition frequencies may be controlled in another manner, for instance, by another type of control signal. In some implementations, the control signal lines may include an inductance loop or another type of flux bias device that is coupled (e.g., conductively, capacitively, or inductively) to a control port to receive control signals, and to the tunable-frequency coupler device 314. In certain instances, the control signals on the control signal lines may cause the flux bias device to generate and modulate the magnetic flux in the superconducting circuit loop of the tunable-frequency coupler device 314.

In some implementations, when the first and second qubit devices 312A, 312B on the first and second quantum processor chips 302A, 302B are coupled through the tunable-frequency coupler device 314, the coupling between the two qubit devices 302A, 302B can be enabled/disabled by tuning a magnetic field applied to the tunable-frequency coupler device 314. When the magnetic flux on the tunable-frequency coupler device 314 is at a parking value, the coupling between the two qubit devices 302A, 302B can be turned off or disabled. When the magnetic flux on the tunable-frequency coupler device 314 is at a gate-activating value, the coupling between the two qubit devices 302A, 302B can be turned on or enabled for performing a multi-qubit quantum logic gate.

FIG. 4 is an equivalent circuit diagram showing aspects of an example tunable-frequency coupler device 400. The example tunable-frequency coupler device 400 may be implemented as the tunable-frequency coupler device 214 in the quantum processor chips 202A, 202B in FIG. 2, the tunable-frequency coupler device 314 in the quantum processor chip 302A in FIGS. 3A-3D, the tunable-frequency coupler device 614 in the cap structure 604 in FIG. 6, and the tunable-frequency coupler device 714 supported by the quantum processor chip 702A and the cap structure 704 in FIG. 7. In some implementations, the example tunable-frequency coupler device 400 is configured to provide tunable coupling between two qubit devices on the same quantum processor chip or on separate, distinct quantum processor chips. The example tunable-frequency coupler device 400 may include additional or different features, and the components may be arranged as shown or in another manner.

In the examples shown in FIG. 4, the example tunable-frequency coupler device 400 is a transmon qubit device with a transition frequency that is tunable, for example, by applying an offset field. The transition frequency is also known as “resonant frequency” or “fundamental frequency”, which is defined by the energy difference between the first and second excited states of the qubit divided by Planck's constant (e.g., according to w=E/h). The transition frequency also defines the operating frequency of the example tunable-frequency coupler device 400.

As shown in FIG. 4, the example tunable-frequency coupler device 400 includes a superconducting circuit loop 406, which can receive a magnetic flux that tunes the transition frequency of the tunable-frequency coupler device 400. As shown, the superconducting circuit loop 406 includes two Josephson junctions 402A, 402B. The two Josephson junctions 402A, 402B having Josephson energies E_{J1} and E_{J2} are connected in parallel with each other forming the superconducting circuit loop 406. In some instances, the example tunable-frequency coupler device 400 is asymmetric, e.g., the two Josephson junctions 402A, 402B have different Josephson junction energies (e.g., E_{J1}<E_{J2}). The asymmetry in the superconducting circuit loop 406 can result in tunability of the tunable-frequency coupler device 400. As shown in FIG. 4, the superconducting circuit loop 406 of the tunable-frequency coupler device 400 is a superconducting quantum interference device (SQUID) loop. In some examples, the superconducting circuit loop 406 of the tunable-frequency coupler device 400 may include one Josephson junction and a linear inductor, more than two Josephson junctions, or in another manner. The example tunable-frequency coupler device 400 further includes a shunt capacitor 404 with a capacitance C_{Jt}, which is connected in parallel with the two Josephson junctions 402A, 402B.

As shown in FIG. 4, the tunable-frequency coupler device 400 includes four terminals, e.g., a first terminal 412A, a second terminal 412B, a third terminal 412C, and a fourth terminal 412D. In some examples, the first and second terminals 412A, 412B may be connected to a first qubit electrode; and the third and fourth terminals can be connected to a second qubit electrode. In this case, the shunt capacitor 404 is formed between the first and second qubit electrodes of the tunable-frequency coupler device 400. In some instances, neither of the first and second qubit electrodes of the tunable-frequency coupler device 400 is galvanically coupled to the ground plane. In other words, the two qubit electrodes can be electrically floating at certain potentials. In some instances, one of the qubit electrodes of the tunable-frequency coupler device 400 may be grounded, e.g., galvanically connected to the ground plane.

In some implementations, the transition frequency of the tunable-frequency coupler device 400 may be defined at least in part by Josephson energies E_{J1}, E_{J2} of the two Josephson junctions 402A, 402B, a capacitance C_{Jt} of the shunt capacitor 404, and a magnetic flux (t) threading the superconducting circuit loop 406. As shown in FIG. 4, the tunable-frequency coupler device 400 includes a flux bias control line 408. In some implementations, the flux bias control line 408 can be a conductor, an inductor (e.g., a partial loop, a single loop, or multiple loops of a conductor), or another type of circuit component that has a mutual inductance with the superconducting circuit loop 406. The flux bias control line 408 can include, for example, a flux bias element that is configured to receive a flux modulation signal and convert the received flux modulation signal to the magnetic field threading the superconducting circuit loop 406. For instance, the flux bias element may include an inductor which is configured to carry a current/and has a mutual inductance with the superconducting circuit loop 406. In some implementations, the flux bias element on the flux bias control line 408 is coupled (e.g., conductively, capacitively, or inductively) to a control port to receive the flux modulation signal from an external control system (e.g., the control system 105 in FIG. 1).

In certain instances, the flux modulation signals on the flux bias control line 408 may cause the flux bias element to generate and modulate the magnetic flux ¢(t) in the superconducting circuit loop 406. Manipulating the magnetic flux ¢(t) through the superconducting circuit loop 406, can increase or decrease the operating frequencies of the example tunable-frequency coupler device 400. In some instances, the operating frequency may be tuned in another manner, for instance, by another type of control signal. In some implementations, the flux modulation signal can be applied to the flux bias element to obtain a modulated magnetic flux applied to the superconducting circuit loop 406. The modulated magnetic flux applied to the superconducting circuit loop 406 can cause a modulation to the transition frequency of the tunable-frequency coupler device 400.

In some instances, the example tunable-frequency coupler device 400 may further include a drive line, which is configured to receive a microwave drive signal, for example, from the control system 105 of FIG. 1. The drive line may be capacitively coupled to the tunable-frequency coupler device 400 via a capacitor (e.g., through one of the two qubit electrodes of the tunable-frequency coupler device 400). The drive signal can be used to control the tunable-frequency coupler device 400, e.g., from one quantum state to a different quantum state.

In some instances, the flux bias control line 408 may reside, together with other superconducting circuit elements (e.g., the superconducting circuit loop 406 and the shunt capacitor 404) of the tunable-frequency coupler device 400, on the same substrate of a quantum processor chip (e.g., the first substrate 306A in FIGS. 3A-3D) or on the same substrate of a cap structure (e.g., the third substrate 608 in FIG. 6). In some instances, the flux bias control line 408 may reside on a cap structure which is separated from the other circuit elements of the tunable-frequency coupler device 400. In this case, after bonding the cap structure with the quantum processor chip, the flux bias control line 408 on the cap structure resides, for example, over the superconducting circuit loop 406 on the quantum processing module, to inductively couple with the superconducting circuit loop 406.

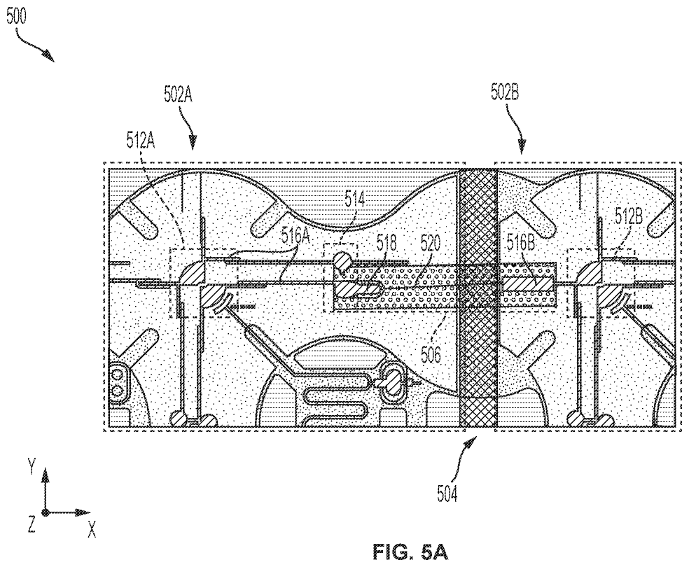

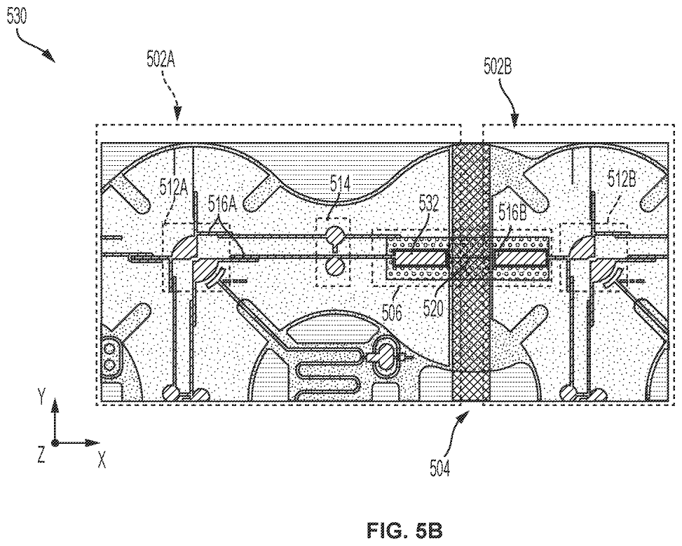

FIGS. 5A-5B are schematic diagrams showing top views of portions of example modular quantum processing units 500, 530. The example modular quantum processing unit 500 is an example physical implementation of the modular quantum processing unit 300C with an equivalent circuit diagram shown in FIG. 3C. Similarly, the example modular quantum processing unit 530 is an example physical implementation of the modular quantum processing unit 300A with an equivalent circuit diagram shown in FIG. 3A. Each of the example modular quantum processing units 500, 530 includes two quantum processor chips 502 (e.g., 502A and 502B) and a cap structure 504. The cap structure 504 includes an inter-chip coupler device 506. The inter-chip coupler device 506 is implemented as a planar microwave transmission line 520. Each of the two quantum processor chips 502A, 502B includes superconductive circuitry and various quantum circuit devices. For example, the quantum processor chip 502A includes a first qubit device 512A and a tunable-frequency coupler device 514, which are capacitively coupled together by a capacitive coupler device 516A. The quantum processor chip 502B includes a second qubit device 512B. The second qubit device 512B is capacitively coupled to the inter-chip coupler device 506 through a capacitive connection 516B. In some instances, the tunable-frequency coupler device 514 is galvanically coupled to the inter-chip coupler device 506 through a galvanic connection 518 as shown in FIG. 5A, and is capacitively coupled to the inter-chip coupler device 506 through a capacitive connection 532 as shown in FIG. 5B.

FIG. 6 is an equivalent circuit diagram of an example modular quantum processing unit 600. The example modular quantum processing unit 600 in FIG. 6 includes a first quantum processor chip 602A, a second quantum processor chip 602B, and a cap structure 604. The first quantum processor chip 602A and the second quantum processor chip 602B can be implemented as the first and second quantum processor chips 202A, 202B in FIG. 2, 302A, 302B in FIGS. 3A-3D, or in another manner. The first quantum processor chip 602A includes a first qubit device 612A, which can be implemented as the qubit device 212A-2 on the first quantum processor chip 202A in FIG. 2, or the first qubit device 312A in FIGS. 3A-3D. Similarly, the second quantum processor chip 602B includes a second qubit device 612B, which may be implemented as the qubit device 212B-1 on the second quantum processor chip 202B in FIG. 2, or the second qubit device 312B in FIGS. 3A-3D. The first quantum processor chip 602A and the second quantum processor chip 602B may include multiple qubit devices which may be arranged as an array shown in FIG. 2 or in another manner.

As shown in FIG. 6, the cap structure 604 includes an inter-chip coupler device 610. The inter-chip coupler device 610 on the cap structure 604 includes a tunable-frequency coupler device 614 and microwave transmission lines 616. In some instances, the tunable-frequency coupler device 614 is implemented as the example tunable-frequency coupler device 400 in FIG. 4 or in another manner. In some implementations, the tunable-frequency coupler device 614 on the cap structure 604 is configured to provide inter-chip coupling between qubit devices on separate quantum processor chips 602A, 602B. The tunable-frequency coupler device 614 is galvanically connected to the microwave transmission lines 616 at the first and second terminals 622A, 622B (e.g., the first and second terminals 412A, 412B of the example tunable-frequency coupler device 400 in FIG. 4). In some implementations, the cap structure 604 further includes control signal lines, such as the flux bias control lines for tuning magnetic flux through a superconducting circuit loop of the tunable-frequency coupler device 614 (e.g., the superconducting circuit loop 406 of the tunable-frequency coupler device 400 in FIG. 4).

As shown in FIG. 6, the first terminal 622A of the tunable-frequency coupler device 614 on the cap structure 604 is capacitively coupled to the first qubit device 612A on the first quantum processor chip 602A, e.g., forming a first capacitive connection 620A; and the second terminal 622B of the tunable-frequency coupler device 614 on the cap structure 604 is capacitively coupled to the second qubit device 612B on the second quantum processor chip 602B, e.g., forming a second capacitive connection 620B. In some examples, the first and second capacitive connections 620A, 620B may be formed by having one capacitor electrode on the cap structure 604 and the other capacitor electrode on the first quantum processor chip 602A or the second quantum processor chip 602B. The two capacitor electrodes are separated by a gap (e.g., vacuum) to form the capacitive connections 620A, 620B. The capacitive connections 620A, 620B allow the tunable-frequency coupler device 614 on the cap structure 604 to be capacitively coupled to the first and second qubit devices 612A, 612B on the first and second quantum processor chips 602A, 602B.

The first qubit device 612A and other superconducting circuit elements (e.g., the conductive lines and capacitor electrode) reside on the surface of a first substrate 606A; the second qubit device 612B and other superconducting circuit elements reside on the surface of a second substrate 606B. The first and second substrates 606A, 606B may be implemented as the substrates 204A, 204B in FIG. 2, or in another manner. The tunable-frequency coupler device 614, control signal lines, and other superconducting circuit element on the cap structure 604 reside on the surface of a third substrate 608, which may be implemented as the third substrate 204C in FIG. 2.

As shown in FIG. 6, ground planes of the first and second quantum processor chips 602A, 602B and the cap structure 604 are galvanically connected together through galvanic connections 620C, 620D, forming a universal ground plane across the modular quantum processing unit 600. In some instances, the galvanic connections 620C, 620D may be formed by superconductive bonding bumps and contact electrodes on respective surfaces when the cap structure 604 is bonded to the first and second quantum processor chips 602A, 602B. In some implementations, control operations can be performed on the superconducting circuit by providing control signals to the tunable-frequency coupler device 614 via control signal lines on the cap structure 604 with respect to operations described in FIGS. 3A-3D.

In some examples, a tunable-frequency coupler device 614 may be separately supported on a coupling chip. The coupling chip and quantum processor chips can be bonded to a common cap structure, which includes superconducting circuitry, for example, microwave transmission lines for propagating microwave signals between quantum processor chips and the coupling chip.

FIG. 7 an equivalent circuit diagram of an example modular quantum processing unit 700. The example modular quantum processing unit 700 shown in FIG. 7 includes a first quantum processor chip 702A, a second quantum processor chip 702B, and a cap structure 704. The first quantum processor chip 702A and the second quantum processor chip 702B can be implemented as the first and second quantum processor chips 202A, 202B in FIG. 2. The first quantum processor chip 702A includes a first superconducting QuIC which includes a first qubit device 712A. The first qubit device 712A can be implemented as the qubit device 212A-2, 312A, 612A in FIGS. 2, 3A-3D, and 6. Similarly, the second quantum processor chip 702B includes a second superconducting QuIC which includes a second qubit device 712B. The second qubit device 712B may be implemented as the qubit device 212B-1, 312B, 612B in FIGS. 2, 3A-3D, and 6. The first quantum processor chip 702A and the second quantum processor chip 702B may include multiple qubit devices which may be arranged as an array shown in FIG. 2 or in another manner.

As shown in FIG. 7, the cap structure 704 includes an inter-chip coupler device 710. The inter-chip coupler device 710 on the cap structure 704 includes a first circuit portion 714A and microwave transmission lines 722. The first QuIC of the first quantum processing module 702A further includes a second circuit portion 714B. The first and second circuit portions 714A, 714B are coupled together through a galvanic connection 720A to form a tunable-frequency coupler device. The tunable-frequency coupler device can be implemented as the example tunable-frequency coupler device 400 in FIG. 4 or in another manner. For example, the first circuit portion 714A includes a shunt capacitor; and the second circuit portion 714B includes a superconducting circuit loop. For another example, the first circuit portion 714A includes a superconducting circuit loop; and the second circuit portion 714B includes a shunt capacitor. For another example, the first circuit portion 714A includes a first capacitor electrode; and the second circuit portion 714B includes a superconducting circuit loop and a second capacitor electrode. The first and second capacitor electrodes are aligned to form a parallel-plate capacitor, when the cap structure 704 is bonded to the first quantum processor chip 702A. For another example, the first circuit portion 714A includes a first Josephson junction; and the second circuit portion 714B includes a second Josephson junction and a shunt capacitor. In this case, when the cap structure 704 is bonded to the first quantum processor chip 702A, the first and second Josephson junctions are connected, for example through bonding bumps and contact pads, in parallel to form a vertical superconducting circuit loop. A flux bias control line can be supported on either the surface of the cap structure 704 or the surface of the first quantum processor chip 702A. In other words, the tunable-frequency coupler device is partially supported by the cap structure 704 and partially supported by the quantum processor chip 702A. This design allows the vacuum gap between the QuIC and the cap to act as the dielectric in the capacitor. This reduces the required area compared to in-plane capacitor designs and more importantly removes or reduces interaction of the electric fields with the substrate material which couples to two level systems that reduce coherence.

As shown in FIG. 7, the second circuit portion 714B is capacitively coupled to the first qubit device 712A through a first capacitive coupler device 718A, which can be implemented as the first capacitive coupler device 318A in FIGS. 3A-3D. The second quantum processor chip 702B further includes a second capacitive coupler device 718B which is galvanically connected to the second qubit device 712B. The first circuit portion 714A is galvanically connected to the second capacitive coupler device 718B, e.g., forming a galvanic connection 720B. The galvanic connections 720A, 720B may be implemented as the galvanic connections 350A, 350B in FIG. 3D, or in another manner.

As shown in FIG. 7, ground planes of the first and second quantum processor chips 702A, 702B and the cap structure 704 are galvanically connected together through galvanic connections 720C, 720D, forming a universal ground plane across the modular quantum processing unit 600. In some instances, the galvanic connections 720C, 720D may be formed by superconductive bonding bumps and contact electrodes on respective surfaces when the cap structure 704 is bonded to the first and second quantum processor chips 702A, 702B. In some implementations, control operations can be performed by providing control signals to the first circuit portion 714A or the second circuit portion 714B via control signal lines on the cap structure 704 or the first quantum processor chip 702A with respect to operations described in FIGS. 3A-3D.

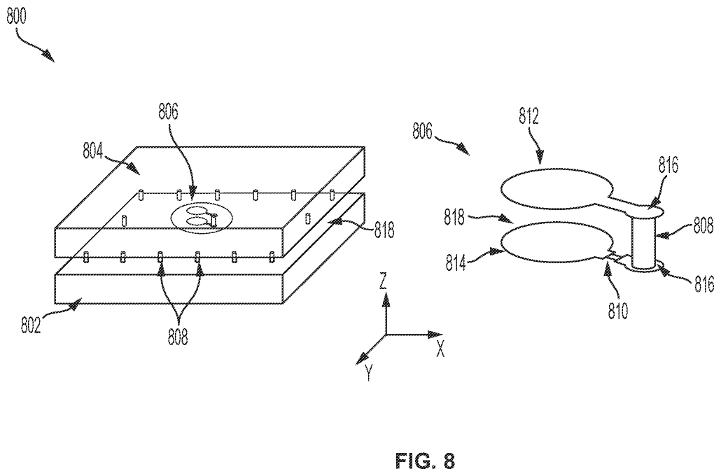

FIG. 8 is a schematic diagram showing aspects of a tunable-frequency coupler device 806 in a modular quantum processing unit 800. The tunable-frequency coupler device 806 includes a superconducting circuit loop 810 and two capacitor electrodes 812, 814. In some implementations, the example modular quantum processing unit 800 may include additional and different features or components and components of the example modular quantum processing unit 800 may be implemented in another manner.

In some implementations, the superconducting circuit loop 810 may be implemented as the superconducting circuit loop 406 in the example tunable-frequency coupler device 400 in FIG. 4; and a shunt capacitor formed between the two capacitor electrodes 812, 814 may be implemented as the shunt capacitor 404 in FIG. 4. The capacitor electrode 812 may be implemented as the first and second terminals 412A, 412B; and the capacitor electrode 814 may be implemented as the third and fourth terminals 412C, 412D. In some instances, control signal lines for controlling magnetic flux in the superconducting circuit loop 810 may reside on the surface of a quantum processor chip 802 or on the surface of a cap structure 804.

As shown in FIG. 8, the capacitor electrode 812 resides on the surface of the cap structure 804; and the capacitor electrode 814 resides on the surface of the quantum processor chip 802. The capacitor electrode 812 may be connected to other superconducting circuit elements in superconducting circuitry on the cap structure 804; and the capacitor electrode 814 may be connected to other superconducting circuit elements in superconducting circuitry on the quantum processor chip 802. For example, the capacitor electrode 812 or 814 may be galvanically or capacitively connected to one end of a planar microwave transmission line on the cap structure 804. The other end of the planar microwave transmission line can be capacitively or galvanically coupled to a superconducting circuit element (e.g., a qubit device or a capacitive coupler device) on a different quantum processor chip for obtaining inter-chip coupling. For another example, the capacitor electrode 814 may be capacitively coupled to a qubit device on the quantum processor chip 802, e.g., directly or through another capacitive coupler device. In certain instances, the capacitor electrode 814 and the superconducting circuit loop 810 may reside on the surface of the cap structure 804 and the capacitor electrode 812 may reside on the surface of the quantum processor chip 802.

When the cap structure 804 and the quantum processor chip 802 are bonded together, the capacitor electrode 812 on the cap structure 804 is aligned with the capacitor electrode 814 on the quantum processor chip 802 along the Z axis. The capacitor electrode 812 on the cap structure 804 is galvanically connected to the superconducting circuit loop 810 on the quantum processor chip 802 through a galvanic connection, e.g., a bonding bump 808 and respective contact pads 816. The capacitor electrodes 812, 814 are separated by a vacuum gap, a thickness of which is defined at least by the height of the bonding bump 808 after bonding.

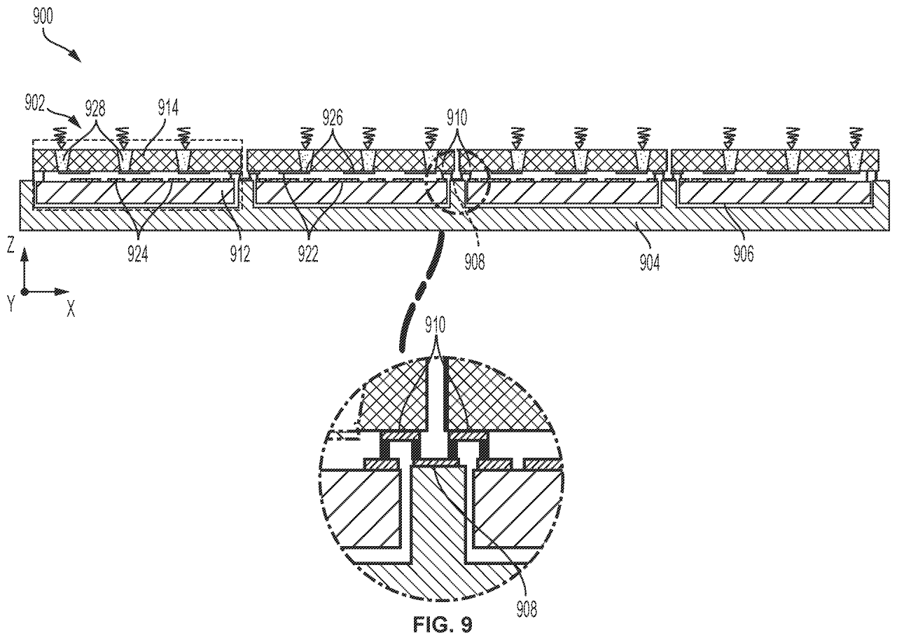

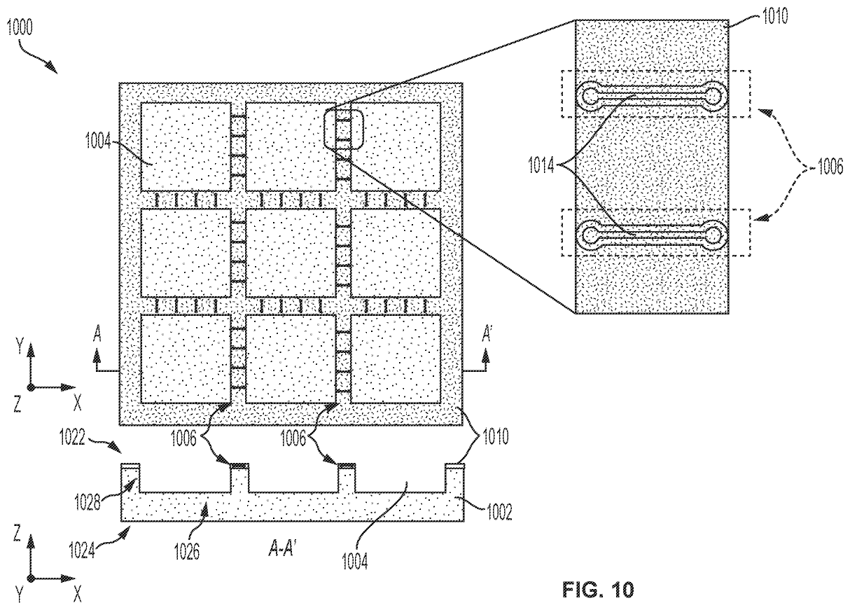

FIG. 9 is a schematic diagram showing a cross-sectional view of an example modular quantum processing unit 900. As shown in FIG. 9, the example modular quantum processing unit includes multiple quantum processor modules 902 bonded on a module integration plate 904. A quantum processor module 902 includes one or more quantum processor chips 912 bonded on a cap structure 914. The module integration plate 904 (e.g., waffle-shape carrier for quantum processor modules 902, or “waffle” carrier) includes recesses 906 that house respective quantum processor chips 912 of quantum processor modules 902. The module integration plate 904 includes inter-module coupler devices 908 between neighboring recesses 906, which enable communication between neighboring quantum processor chips 912 housed in the neighboring recesses 906. In some instances, the module integration plate 904 may be implemented as the module integration plate 1000 in FIG. 10 or in another manner. In some implementations, the example modular quantum processing unit 900 may include additional and different features or components and components of the example modular quantum processing unit 900 may be implemented in another manner.

As shown in FIG. 9, the quantum processor chip 912 includes a superconducting quantum circuit. The superconducting quantum circuit includes qubit devices 922, coupler device 924, and other quantum circuit devices. In some instances, the quantum processor chips 912 may be implemented as the quantum processor chips 202, 302, 502, 602, 702, 802 in FIGS. 2, 3A-3D, 5A-5B, 6, and 8 or in another manner. The cap structure 914 includes signal lines 926 and conductive vias 928 to communicate control signals to the respective quantum circuit devices of the quantum processor chips 912. The cap structure 914 also includes inter-chip coupler devices 910. In some in stances, the cap structure 914 may be implemented as the cap structure 206, 304, 504, 604, 704, 804 in FIGS. 2, 3A-3D, 5A-5B, 6, 7, and 8 or in another manner; and the inter-chip coupler device 910 may be implemented as the inter-chip coupler device 222, 322, 506, 610, 710 in FIGS. 2, 3A-3D, 5A-5B, 6, and 7, or in another manner.

As shown in FIG. 9, the module integration plate 904 includes multiple recesses 906, each of which is defined by a recessed surface and sidewalls. Recesses on the module integration plate 904 form respective enclosures that house the respective quantum processor chips 912 on the respective quantum processor module 902. In some instances, a recess 906 of the module integration plate 904 may include multiple recessed surfaces with different depths and shapes. In some instances, the recesses 906 of a module integration plate 904 may have different shapes and sizes according to the design of the quantum processor chips 912 and the cap structures 914 of the quantum processor modules 902.

In some implementations, an inter-module coupler device 908 includes a microwave transmission line (e.g., the microwave transmission line 1012 in FIG. 10) which is electrically connected to respective inter-chip coupler devices 910 of the respective cap structures 914. In some instances, an electrical connection between an inter-module coupler device 908 and an inter-chip coupler device 910 of a cap structure 914 may be galvanic, capacitive, or inductive. In this case, coupling between two quantum processor chips 912 are achieved by inter-chip coupling devices 910 of the cap structure 914 and respective inter-module coupler devices 908 of the module integration plate 904. In some implementations, the inter-module coupler device 908 on the module integration plate 904 and associated inter-chip coupler devices 910 on the cap structures 914 route coherent microwave signals between qubit devices 924 on the associated quantum processor chips 912 via the cap structures 914, and the module integration plate 904.

As shown in FIG. 9, the module integration plate 904 has a monolithic structure configured for housing all quantum processor chips 912 in the example modular quantum processing unit 900. In some implementations, the module integration plate 1000 can simplify processing steps to interconnect multiple quantum processor chips, facilitate the scaling of the quantum processing unit, and provide greater capital efficiency. In some instances, the example modular quantum processing unit 900 may include multiple module integration plates 904; and each module integration plate 904 is configured for housing a subset of the quantum processor chips 912. In certain examples, the multiple module integration plates 1408 may be interconnected, supported, or otherwise integrated by a common plate or in another manner.

FIG. 10 is a schematic diagram showing top-view and cross-sectional view of an example module integration plate 1000. The example module integration plate 1000 is configured to support and integrate quantum processor modules to form a modular quantum processing unit. As shown in FIG. 9, the module integration plate 1000 includes recesses 1004 formed on a substrate 1002. The substrate 1002 includes a first surface 1022 and a second surface 1024. A ground plane 1010 is disposed on the first surface 1022. The ground plane 1010 may be continuous across the first surface 1022 of the substrate 1002.

As shown in FIG. 10, the recesses 1004 are organized in the substrate 1002 as an array. Each of the recesses 1004 is defined by a recessed surface 1026 and sidewalls 1028. The recessed surface 1026 is located at a depth in the substrate 1002 relative to the first surface 1022. In some implementations, each of the recesses 1004 may be a cavity, a shallow trench, a deep trench, or in another form. Dimension and shape of a recess 1004 may be determined according to the dimension and shape of the quantum processor chip associated with or enclosed by the recess 1004, and/or the dimension and shape of the cap structure interconnected with and supported by the module integration plate 1000. As shown in FIG. 10, each of the recesses 1004 has vertical sidewalls 1028 along the Z-direction perpendicular to the first and second surfaces 1022, 1024. In certain implementations, the recesses 1004 may include angled or sloped sidewalls 1028 between the first surface 1022 and the recessed surface 1026.

In some implementations, the module integration plate 1000 includes inter-module coupler devices 1006 at ridges between recesses 1004 on the first surface 1022. The inter-module coupler devices 1006 enable coupling between quantum processor chips that are housed in distinct recesses 1004. In some instances, the module integration plate 1000 may include other superconducting circuitry that can carry signals at other surfaces (e.g., the second surface 1024 of the module integration plate 1000). In some instances, the example modular integrate plate 1000 may be implemented as the module integration plate 904 of the modular quantum processing unit 900 in FIG. 9. In some implementations, the module integration plate 1000 is fabricated on a silicon wafer, a PCB substrate, or another type of substrate.

In some implementations, the inter-module coupler devices 1006 are electrically connected to inter-chip coupler devices of the cap structure (e.g., the inter-chip coupler devices 910 of the cap structure 914). In some implementations, the connections of each of the inter-module coupler devices 1006 to the inter-chip coupler devices of the cap structure include a galvanic connection (e.g., a bonding bump), a capacitive connection (e.g., a pair of capacitive electrodes), or an inductive connection. As shown in FIG. 10, the inter-module coupler device 1006 includes a microwave transmission line 1014. In some instances, the microwave transmission line 1014 may be implemented as coplanar waveguides, substrate integrated waveguides, or another type of planar transmission line structure.

In a general aspect, a modular quantum processing unit includes quantum processor chips that are inter-connected by a cap structure.

In a first example, a modular quantum processing unit includes a tunable-frequency coupler device, a first quantum processor chip, a second quantum processor chip, and a cap structure. The tunable-frequency coupler device includes a superconducting quantum interference device (SQUID) loop, a shunt capacitor, and a flux bias control line that controls a magnetic flux through the SQUID loop. The first quantum processor chip includes a first qubit device, the SQUID loop, the flux bias control line, and a first capacitive coupler device galvanically connected between the first qubit device and the tunable-frequency coupler device. The second quantum processor chip includes a second qubit device. The cap structure, including a microwave transmission line capacitively coupled between the tunable-frequency coupler device and the second qubit device, is bonded to the first and second quantum processor chips.

Implementations of the first example may include one or more of the following features. The second quantum processor chip further includes a second capacitive coupler device galvanically connected to the second qubit device. The microwave transmission line includes a first galvanic connection to the tunable-frequency coupler device, and a second galvanic connection to the second capacitive coupler device. The first galvanic connection includes a first bonding bump between the cap structure and the first quantum processor chip. The second galvanic connection includes a second bonding bump between the cap structure and the second quantum processor chip.

Implementations of the first example may include one or more of the following features. The microwave transmission line includes a galvanic connection to the tunable-frequency coupler device, and at least part of a capacitive connection to the second qubit device. The galvanic connection includes a bonding bump between the cap structure and the first quantum processor chip. The capacitive connection includes a first capacitor electrode on the cap structure and a second capacitor electrode on the second quantum processor chip.

Implementations of the first example may include one or more of the following features. The microwave transmission line includes at least part of a first capacitive connection to the tunable-frequency coupler device; and at least part of a second capacitive connection to the second qubit device. The first capacitive connection includes a first capacitor electrode on the cap structure and a second capacitor electrode on the first quantum processor chip. The second capacitive connection includes a third capacitor electrode on the cap structure and a fourth capacitor electrode on the second quantum processor chip.

Implementations of the first example may include one or more of the following features. The second quantum processor chip further includes a second capacitive coupler device galvanically connected to the second qubit device. The microwave transmission line includes at least part of a capacitive connection to the tunable-frequency coupler device, and a galvanic connection to the second capacitive coupler device. The capacitive connection includes a first capacitor electrode on the cap structure and a second capacitor electrode on the first quantum processor chip. The galvanic connection includes a bonding bump between the cap structure and the second quantum processor chip.

Implementations of the first example may include one or more of the following features. The flux bias control line includes a flux bias device that is operable to tune a frequency of the tunable-frequency coupler device. The first qubit device includes a first tunable-frequency qubit device. The first quantum processor chip includes a first flux bias device that is operable to tune a frequency of the first tunable-frequency qubit device. The second qubit device includes a second tunable-frequency qubit device. The second quantum processor chip includes a second flux bias device that is operable to tune a frequency of the second tunable-frequency qubit device. The first quantum processor chip includes a first drive line operable to communicate microwave control signals to the first qubit device. The second quantum processor chip includes a second drive line operable to communicate microwave control signals to the second qubit device. The cap structure comprises a first recess that houses the first qubit device, and a second recess that houses the second qubit device. The first quantum processor chip and the second quantum processor chip are both supported on a common substrate. The common substrate includes signal lines configured to communicate signals between the first qubit device and an external control system; and signal lines configured to communicate signals between the second qubit device and the external control system.

In a second example, a modular quantum processing unit includes a first quantum processor chip, a second quantum processor chip, and a cap structure. The first quantum processor chip includes a first qubit device, at least a portion of a tunable-frequency coupler device, and a first capacitive coupler device galvanically connected between the first qubit device and the tunable-frequency coupler device. The second quantum processor chip includes a second qubit device. The cap structure bonded to the first quantum processor chip and the second quantum processor chip includes a microwave transmission line that is capacitively coupled between the tunable-frequency coupler device and the second qubit device.

Implementations of the second example may include one or more of the following features. The tunable-frequency coupler device includes a lossless resonator device. The tunable-frequency coupler device includes a SQUID loop, a shunt capacitor, and a flux bias control line.

In a third example, a computing system includes the modular quantum processing unit described in the first and second examples.

In a fourth example, a computing method includes operating the modular quantum processing unit described in the first and second examples.

In a fifth example, a computing method includes storing information in a first qubit device on a first quantum processor chip and a second qubit device on a second quantum processor chip in a modular quantum processing unit, and processing the information by operation of the modular quantum processing unit. The modular quantum processing unit includes a tunable-frequency coupler device, the first quantum processor chip, and a cap structure. The tunable-frequency coupler device includes a superconducting quantum interference device (SQUID) loop, a shunt capacitor, and a flux bias control line. The first quantum processor chip includes the SQUID loop; the flux bias control line that controls a magnetic flux through the SQUID loop; and a first capacitive coupler device galvanically connected between the first qubit device and the tunable-frequency coupler device. The cap structure bonded to at least one of the first quantum processor chip or the second quantum processor chip. The cap structure includes a microwave transmission line that is capacitively coupled between the tunable-frequency coupler device and the second qubit device. Processing the information includes operating the tunable-frequency coupler device to selectively couple the first qubit device with the second qubit device.

Implementations of the fifth example may include one or more of the following features. The second quantum processor chip further includes a second capacitive coupler device galvanically connected to the second qubit device, and the microwave transmission line includes a first galvanic connection to the tunable-frequency coupler device; and a second galvanic connection to the second capacitive coupler device. The first galvanic connection includes a first bonding bump between the cap structure and the first quantum processor chip; and the second galvanic connection includes a second bonding bump between the cap structure and the second quantum processor chip. The cap structure is bonded to the first quantum processor chip and the second quantum processor chip.

Implementations of the fifth example may include one or more of the following features. The microwave transmission line includes a galvanic connection to the tunable-frequency coupler device; and at least part of a capacitive connection to the second qubit device. The galvanic connection includes a bonding bump between the cap structure and the first quantum processor chip; and the capacitive connection includes a first capacitor electrode on the cap structure and a second capacitor electrode on the second quantum processor chip.

Implementations of the fifth example may include one or more of the following features. The microwave transmission line includes at least part of a first capacitive connection to the tunable-frequency coupler device; and at least part of a second capacitive connection to the second qubit device. The first capacitive connection includes a first capacitor electrode on the cap structure and a second capacitor electrode on the first quantum processor chip; and the second capacitive connection includes a third capacitor electrode on the cap structure and a fourth capacitor electrode on the second quantum processor chip.

Implementations of the fifth example may include one or more of the following features. The first quantum processor chip includes a plurality of first qubit devices, the second quantum processor chip includes a plurality of second qubit devices, and the microwave transmission line is configured to selectively couple at least a subset of the plurality of first qubit devices and at least a subset of the plurality of second qubit devices.

Implementations of the fifth example may include one or more of the following features. The second quantum processor chip further includes a second capacitive coupler device galvanically connected to the second qubit device, and the microwave transmission line includes at least part of a capacitive connection to the tunable-frequency coupler device; and a galvanic connection to the second capacitive coupler device. The capacitive connection includes a first capacitor electrode on the cap structure and a second capacitor electrode on the first quantum processor chip; and the galvanic connection includes a bonding bump between the cap structure and the second quantum processor chip.

Implementations of the fifth example may include one or more of the following features. The flux bias control line includes a flux bias device that is operable to tune a frequency of the tunable-frequency coupler device. The first qubit device includes a first tunable-frequency qubit device, and the first quantum processor chip includes a first flux bias device that is operable to tune a frequency of the first tunable-frequency qubit device; and the second qubit device includes a second tunable-frequency qubit device, and the second quantum processor chip includes a second flux bias device that is operable to tune a frequency of the second tunable-frequency qubit device. The first quantum processor chip includes a first drive line operable to communicate microwave control signals to the first qubit device; and the second quantum processor chip includes a second drive line operable to communicate microwave control signals to the second qubit device.

Implementations of the fifth example may include one or more of the following features. The cap structure includes a first recess that houses the first qubit device, and a second recess that houses the second qubit device. The first quantum processor chip and the second quantum processor chip are both supported on a common substrate. The common substrate includes signal lines configured to communicate signals between the first qubit device and an external control system; and signal lines configured to communicate signals between the second qubit device and the external control system. The common substrate includes a first recess that houses the first quantum processor chip; a second, distinct recess that houses the second quantum processor chip; and an inter-module coupler device that provides communication between the microwave transmission line and the second qubit device. The cap structure is a first cap structure bonded to the first quantum processor chip. The modular quantum processing unit includes a second cap structure bonded to the second quantum processor chip. The microwave transmission line includes a first microwave transmission line; the second cap structure includes a second microwave transmission line; and each of the inter-module coupler devices includes a third microwave transmission line coupled between the first and second microwave transmission lines.

While this specification contains many details, these should not be understood as limitations on the scope of what may be claimed, but rather as descriptions of features specific to particular examples. Certain features that are described in this specification or shown in the drawings in the context of separate implementations can also be combined. Conversely, various features that are described or shown in the context of a single implementation can also be implemented in multiple implementations separately or in any suitable sub-combination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the implementations described above should not be understood as requiring such separation in all implementations, and it should be understood that the described program components and systems can generally be integrated together in a single product or packaged into multiple products.

A number of embodiments have been described. Nevertheless, it will be understood that various modifications can be made. Accordingly, other embodiments are within the scope of the following claims.

1. A modular quantum processing unit comprising:
a tunable-frequency coupler device comprising a superconducting quantum interference device (SQUID) loop, a shunt capacitor, and a flux bias control line;
a first quantum processor chip comprising:
a first qubit device;
the SQUID loop;
the flux bias control line that controls a magnetic flux through the SQUID loop; and
a first capacitive coupler device galvanically connected between the first qubit device and the tunable-frequency coupler device;
a second quantum processor chip comprising a second qubit device;
a cap structure bonded to at least one of the first quantum processor chip or the second quantum processor chip, the cap structure comprising a microwave transmission line that is capacitively coupled between the tunable-frequency coupler device and the second qubit device.

2. The modular quantum processing unit of claim 1, wherein the second quantum processor chip further comprises a second capacitive coupler device galvanically connected to the second qubit device, and the microwave transmission line comprises:
a first galvanic connection to the tunable-frequency coupler device; and
a second galvanic connection to the second capacitive coupler device.

3. The modular quantum processing unit of claim 2, wherein:
the first galvanic connection comprises a first bonding bump between the cap structure and the first quantum processor chip; and
the second galvanic connection comprises a second bonding bump between the cap structure and the second quantum processor chip.

4. The modular quantum processing unit of claim 1, wherein the cap structure is bonded to the first quantum processor chip and the second quantum processor chip.

5. The modular quantum processing unit of claim 1, wherein the microwave transmission line comprises:
a galvanic connection to the tunable-frequency coupler device; and
at least part of a capacitive connection to the second qubit device.

6. The modular quantum processing unit of claim 5, wherein:
the galvanic connection comprises a bonding bump between the cap structure and the first quantum processor chip; and
the capacitive connection comprises a first capacitor electrode on the cap structure and a second capacitor electrode on the second quantum processor chip.

7. The modular quantum processing unit of claim 1, wherein the microwave transmission line comprises:
at least part of a first capacitive connection to the tunable-frequency coupler device; and
at least part of a second capacitive connection to the second qubit device.

8. The modular quantum processing unit of claim 7, wherein:
the first capacitive connection comprises a first capacitor electrode on the cap structure and a second capacitor electrode on the first quantum processor chip; and
the second capacitive connection comprises a third capacitor electrode on the cap structure and a fourth capacitor electrode on the second quantum processor chip.

9. The modular quantum processing unit of claim 1, wherein the first quantum processor chip comprises a plurality of first qubit devices, the second quantum processor chip comprises a plurality of second qubit devices, and the microwave transmission line of the cap structure is configured to selectively couple at least a subset of the plurality of first qubit devices and at least a subset of the plurality of second qubit devices.

10. The modular quantum processing unit of claim 1, wherein the second quantum processor chip further comprises a second capacitive coupler device galvanically connected to the second qubit device, and the microwave transmission line comprises:
at least part of a capacitive connection to the tunable-frequency coupler device; and
a galvanic connection to the second capacitive coupler device.

11-24. (canceled)

25. A computing method comprising:
storing information in a first qubit device on a first quantum processor chip and a second qubit device on a second quantum processor chip in a modular quantum processing unit, wherein the modular quantum processing unit comprises:
a tunable-frequency coupler device comprising a superconducting quantum interference device (SQUID) loop, a shunt capacitor, and a flux bias control line;
the first quantum processor chip, which comprises:
the SQUID loop;
the flux bias control line that controls a magnetic flux through the SQUID loop; and
a first capacitive coupler device galvanically connected between the first qubit device and the tunable-frequency coupler device; and
a cap structure bonded to at least one of the first quantum processor chip or the second quantum processor chip, the cap structure comprising a microwave transmission line that is capacitively coupled between the tunable-frequency coupler device and the second qubit device; and
processing the information by operation of the modular quantum processing unit, wherein processing the information comprises operating the tunable-frequency coupler device to selectively couple the first qubit device with the second qubit device.

26. The computing method of claim 25, wherein the second quantum processor chip further comprises a second capacitive coupler device galvanically connected to the second qubit device, and the microwave transmission line comprises:
a first galvanic connection to the tunable-frequency coupler device; and
a second galvanic connection to the second capacitive coupler device.

27. The computing method of claim 26, wherein:
the first galvanic connection comprises a first bonding bump between the cap structure and the first quantum processor chip; and
the second galvanic connection comprises a second bonding bump between the cap structure and the second quantum processor chip.

28. The computing method of claim 25, wherein the cap structure is bonded to the first quantum processor chip and the second quantum processor chip.

29. The computing method of claim 25, wherein the microwave transmission line comprises:
a galvanic connection to the tunable-frequency coupler device; and
at least part of a capacitive connection to the second qubit device.

30. The computing method of claim 29, wherein:
the galvanic connection comprises a bonding bump between the cap structure and the first quantum processor chip; and
the capacitive connection comprises a first capacitor electrode on the cap structure and a second capacitor electrode on the second quantum processor chip.

31. The computing method of claim 25, wherein the microwave transmission line comprises:
at least part of a first capacitive connection to the tunable-frequency coupler device; and
at least part of a second capacitive connection to the second qubit device.

32. The computing method of claim 31, wherein:
the first capacitive connection comprises a first capacitor electrode on the cap structure and a second capacitor electrode on the first quantum processor chip; and
the second capacitive connection comprises a third capacitor electrode on the cap structure and a fourth capacitor electrode on the second quantum processor chip.

33. The computing method of claim 25, wherein the first quantum processor chip comprises a plurality of first qubit devices, the second quantum processor chip comprises a plurality of second qubit devices, and the microwave transmission line is configured to selectively couple at least a subset of the plurality of first qubit devices and at least a subset of the plurality of second qubit devices.

34. The computing method of claim 25, wherein the second quantum processor chip further comprises a second capacitive coupler device galvanically connected to the second qubit device, and the microwave transmission line comprises:
at least part of a capacitive connection to the tunable-frequency coupler device; and
a galvanic connection to the second capacitive coupler device.

35-43. (canceled)
